(19) United States
(12) Patent Application Publication
(10) Pub. No.: US 2015/0010721 A1
(43) Pub. Date: Jan. 8, 2015

(54) GLASS CERAMIC BODY, LAYERED BODY, PORTABLE ELECTRONIC DEVICE HOUSING, AND PORTABLE ELECTRONIC DEVICE

(71) Applicant: ASAHI GLASS COMPANY, LIMITED, Chiyoda-ku (JP)

(72) Inventors: Masamichi TANIDA, Tokyo (JP); Seigo OHTA, Tokyo (JP); Hideki NUMAKURA, Tokyo (JP)

(73) Assignee: ASAHI GLASS COMPANY, LIMITED, Chiyoda-ku (JP)

(21) Appl. No.: 14/481,387

(22) Filed: Sep. 9, 2014

Related U.S. Application Data
(63) Continuation of application No. PCT/JP2013/056084, filed on Mar. 6, 2013.

(30) Foreign Application Priority Data
Mar. 9, 2012 (JP) 2012-053447
Jun. 28, 2012 (JP) 2012-145058
Oct. 4, 2012 (JP) 2012-222374

(51) Int. Cl. C03C 14/00; H05K 5/00

(52) U.S. Cl. CPC C03C 14/004; H05K 5/0086; C03C 2214/20; C03C 2214/04
USPC 428/34.5; 252/582; 428/221; 428/329

(57) ABSTRACT

There are provided a glass ceramic body having a sufficiently high strength and having a high degree of flexibility in shape which can correspond to a three-dimensional shape, and a layered body having the glass ceramic body. In a glass ceramic body in which flat alumina particles are dispersed in a glass matrix constituted of a glass with a crystallinity of 25% or less, a total cross-sectional area of the flat alumina particles, having a cross section with a thickness of 0.2 μm or more, a maximum diameter of 8 μm or less, and an aspect ratio in a range of 3 to 18 in one of cross sections along the thickness directions of the flat alumina particles in the glass ceramic body, is 20% or more relative to a total area of the cross section, and an open porosity is 5% or less.

### CROSS-REFERENCE TO RELATED APPLICATIONS

This application is a continuation of prior International Application No. PCT/JP2013/056084 filed on Mar. 6, 2013, which is based upon and claims the benefit of priority from Japanese Patent Applications No. 2012-053447 filed on Mar. 9, 2012, No. 2012-145058 filed on Jun. 28, 2012, and No. 2012-222374 filed on Oct. 4, 2012; the entire contents of all of which are incorporated herein by reference.

### TECHNICAL FIELD

The present invention relates to a glass ceramic body, a layered body, a portable electronic device housing, and a portable electronic device.

### BACKGROUND

As a wiring substrate used for electronic devices, a glass ceramic substrate constituted of a sintered compact of a composition containing glass powder and ceramic powder is known. A conductive pattern is formed, for example, on a surface of or inside the glass ceramic substrate, and the substrate is mounted as a wiring substrate in an electronic device. Alternatively, no particular wiring is provided, and it is used as a housing for an electronic device such as a portable phone.

In recent years, accompanying size reduction and increase in function of electronic devices, thinning of glass ceramic substrate is demanded. Moreover, electrode structures are becoming complicated accompanying complication and micronization of circuit boards, and stress applied to a glass ceramic substrate is increasing. Accordingly, a glass ceramic substrate having a higher strength than conventional ones is demanded now. Further, when it is used for an element mounting substrate for LED or a housing for electronic device or the like, a glass ceramic substrate having a sufficient strength and also having a three-dimensional shape is demanded.

Here, the glass ceramic substrate contains glass as a main component, and has a nature that it is inherently weak against shock and a crack easily occurs. Accordingly, attempts have been made hitherto to obtain a glass ceramic substrate that can correspond to thinning and high strength, by choosing one that can contribute to improvement in strength of an obtained glass ceramic substrate as the compounded ceramic powder, or the like.

For example, for the purpose of increasing heat conductivity and increasing strength of the glass ceramic substrate, Patent Reference 1 (JP-A 2002-111210) proposes a glass ceramic substrate in which flat ceramic particles having an aspect ratio of four or more are dispersed in a glass matrix with a high orientation degree of 50% or more. Here, in the glass ceramic substrate proposed by Patent Reference 1, strength is improved compared to conventional ones, but it is hard to say that it has reached a level that can correspond sufficiently to high strength demanded in recent years.

Further, Patent Reference 2 (JP-A 2010-100517) proposes a technique to obtain high-strength wiring substrate by improving the orientation of flat alumina particles by bound layering a green sheet using flat alumina particles having an aspect ratio of 50 to 80 with another green sheet having a small thermal contraction and firing it. Moreover, Patent Reference 3 (JP-A 2011-176210) proposes a technique to make, by a similar method, a high-strength wiring substrate from a green sheet using flat alumina particles having an aspect ratio of 20 or more.

Since the flat alumina particles having a high aspect ratio and a high specific surface area are used in Patent References 2, 3, a dispersion failure of alumina particles is anticipated, and it is conceivable that a dispersion in strength occurs due to this. Accordingly, in the Patent References 2, 3, for the purpose of suppressing the dispersion in strength, a method is employed to layer other green sheets having a small thermal contraction so as to sandwich the green sheet. In this method, there is a problem that, for example, it is structurally restricted largely when manufacturing a glass ceramic body having a three-dimensional shape.

Further, as a housing material for portable electronic device, there are known a resin material, a material in which organic paint is applied on a glass material, a material in which an inorganic material is fired on a glass material, a frost glass material, a ceramic material, a glass ceramic material, and the like (see, for example, Patent Reference 4 (WO 2010/002477 A1)).

However, regarding the resin material, a high-grade appearance cannot always be obtained. Regarding the material in which organic paint is applied on a glass material, the material in which an inorganic material is fired on a glass material, and the frost glass material, a high-grade appearance can be obtained compared to the resin material, but there is large diffuse transmission light and thus it is not always excellent in light shielding property. Regarding the ceramic material and the glass ceramic material, a high-grade appearance can be obtained and a light shielding property increases compared to the above materials, but the light shielding property is not always sufficient.

In recent years, in a portable electronic device, for example a portable phone, a smart phone, or the like, there are cases where an imaging part or flash part is provided on a rear surface part. In this case, an opening is provided in a part of a housing to be the rear surface part, and the imaging part or flash part is disposed in this part. However, when the light shielding property of the housing material is low, not only the opening is brightened when the flash part is used, but also a surrounding part on the outside can be brightened by a flash light which is transmitted through the housing, by which a high-grade appearance may not always be obtained.

In particular, white housings are preferred in recent years, but there are few white materials by which a high-grade appearance can be obtained and which has a high light shielding property. Further, as the housing for the portable electronic device, not only a high-grade appearance and a high light shielding property are required, but also high strength is required for suppressing destruction due to a shock when dropped or the like.

### SUMMARY

The present invention has been made to solve the above problems, and it is an object thereof to provide a glass ceramic body, a layered body, and a portable electronic device housing having a sufficiently high strength and having a high degree of flexibility in shape which can correspond to a three-dimensional shape.

A glass ceramic body of a first aspect is obtained by forming a glass ceramic composition into a green sheet and thereafter firing the green sheet. The glass ceramic composition contains glass particles and flat alumina particles. The flat alumina particles have a mean thickness of 0.4 μm or more, a mean major axis of 10 μm or less, and a mean aspect ratio of 3 to 18. The glass ceramic composition contains the flat alumina particles by 25 vol % or more. In the glass ceramic body of the first aspect, the flat alumina particles are dispersed in a glass matrix constituted of a glass with a crystallinity of 25% or less. Further, in the glass ceramic body of the first aspect, an open porosity is 5% or less.

In a glass ceramic body of a second aspect, flat alumina particles are dispersed in a glass matrix. The glass matrix is constituted of a glass with a crystallinity of 25% or less. The flat alumina particles are dispersed in the glass matrix so that individual thickness directions are substantially perpendicular to a surface direction of one of surfaces of the glass ceramic body. A total cross-sectional area of the flat alumina particles, having a cross section with a thickness of 0.2 μm or more, a maximum diameter of 8 μm or less, and an aspect ratio in a range of 3 to 18 in one of cross sections along the thickness directions of the flat alumina particles in the glass ceramic body, is 20% or more relative to a total area of the cross section of the glass ceramic body. In the glass ceramic body of the second aspect, an open porosity is 5% or less.

The present invention provides a layered body having at least one glass ceramic body selected from the glass ceramic body of the first aspect and the glass ceramic body of the second aspect. Note that in this description, at least one means that it may be one or may be a combination of two or more.

A portable electronic device housing of the first aspect has at least one glass ceramic body selected from the glass ceramic body of the first aspect and the glass ceramic body of the second aspect.

A portable electronic device housing of the second aspect has a high reflectivity layer constituted of a glass ceramic body, and has reflectivity of 92% or more in a wavelength range of at least 400 to 800 nm.

The present invention provides a portable electronic device having the portable electronic device housing.

Note that in this description, unless otherwise noted in particular, substantially perpendicular and substantially parallel refer to being recognizable as perpendicular and parallel, respectively, at a visual observation level in an image analysis screen by a microscope or the like or in actual observation.

According to the present invention, a glass ceramic body having a sufficiently high strength and having a high degree of flexibility in shape which can correspond to a three-dimensional shape and a layered body having the glass ceramic body can be provided. Further, a portable electronic device housing having a sufficiently high strength and a portable electronic device having the portable electronic device housing can be provided.

### BRIEF DESCRIPTION OF THE DRAWINGS

FIG. 1 is an exterior view illustrating one embodiment of a glass ceramic body of a second aspect.

FIG. 2 is a schematic cross-sectional view in a cross section A of the glass ceramic body illustrated in FIG. 1.

FIG. 3 is a schematic cross-sectional view in a cross section B of the glass ceramic body illustrated in FIG. 1.

FIG. 4 is a graph of spectrum of X-ray diffraction (XRD) of the glass ceramic body of an example (example 14).

FIG. 5 is a plan view illustrating one embodiment of a portable electronic device.

FIG. 6 is a cross-sectional view illustrating an example of a housing.

FIG. 7 is a cross-sectional view illustrating an example of a housing having low thermal expansion layers.

FIG. 8 is a cross-sectional view illustrating an example of a housing having low contraction layers.

FIG. 9 is a schematic perspective view illustrating an example of a low contraction layer.

FIG. 10 is a schematic cross-sectional view illustrating an example of the low contraction layer.

FIG. 11 is a cross-sectional view illustrating an example of a housing having glassy layers.

FIG. 12 is a cross-sectional view illustrating a modification example of a housing having glassy layers.

FIG. 13 is a cross-sectional view illustrating another modification example of a housing having glassy layers.

FIG. 14 is a plan view illustrating another embodiment of a portable electronic device.

FIG. 15 is an A-A arrow cross sectional view of the portable electronic device illustrated in FIG. 14.

FIG. 16 is a diagram illustrating a spectral reflectivity of example 24.

### DETAILED DESCRIPTION

Hereinafter, embodiments of the present invention will be described in detail.

### [Glass Ceramic Body of a First Aspect]

A glass ceramic body of a first aspect of the present invention is a glass ceramic body obtained by forming a glass ceramic composition into a green sheet and thereafter firing the green sheet, the glass ceramic composition containing glass particles and flat alumina particles having a mean thickness of 0.4 μm or more, a mean major axis of 10 μm or less, and a mean aspect ratio of 3 to 18, the content of the flat alumina particles being 25 vol % or more, wherein the flat alumina particles are dispersed in a glass matrix constituted of a glass with a crystallinity of 25% or less, and an open porosity of the glass ceramic body is 5% or less.

The glass ceramic body of the first aspect is a glass ceramic body in which the flat alumina particles are dispersed in the glass matrix obtained by firing the glass ceramic composition of the above structure.

Here, the relation between the glass ceramic composition used and the glass ceramic body obtained is as follows.

Upon firing, the glass particles contained in the glass ceramic composition melt, and the flat alumina particles are dispersed in this molten glass. Further, in the firing process, the vicinity of a surface of a flat alumina particle liquates into the molten glass.

By this liquation, the size of the flat alumina particles in the glass ceramic body after firing decreases compared to that before firing, but regarding the mode of a flat body, the mode of a raw material before firing is mostly maintained after firing. Further, in the firing process, alumina components which liquated from the flat alumina particles disperse in the molten glass, and thus the glass matrix in the glass ceramic body obtained after firing has a composition in which the alumina components of the liquated amount are added to the glass composition of the glass particles.

The first aspect of the present invention is a glass ceramic body, in which the flat alumina particles are dispersed in a glass matrix constituted of a glass with a crystallinity of 25% or less, and an open porosity of it is 5% or less. Thus, it becomes a glass ceramic body having a sufficiently high strength and having a high degree of flexibility in shape which can correspond to a three-dimensional shape.

Here, the crystallinity of the glass constituting the glass matrix of the glass ceramic body can be calculated by the following calculation formula (1) from an X-ray diffraction spectrum of the glass ceramic body measured with an X-ray diffraction apparatus.

Crystallinity(%)=I(glass)/{I(Al₂O₃)+I(glass)}×100 (1)

In the formula (1), I(glass) denotes the maximum intensity of a peak of X-ray diffraction of crystallized glass, and I(Al₂O₃) denotes the maximum intensity of a peak of X-ray diffraction of alumina. Note that a characteristic X ray can be measured by using a CuKα ray.

In this description, the crystallinity of glass refers to one measured by the above method. In the first aspect of the present invention, the crystallinity measured in this method of the glass constituting the glass matrix is 25% or less.

The glass matrix having a crystallized glass means that crystals separate from the glass composition constituted of glass particle components and alumina components which liquated from flat alumina particles during manufacturing, and exist in the glass matrix. When the glass matrix has glass crystals as a lump of partially crystallized glass, it is possible that a crack proceeds from a glass crystal grain boundary, and strength decreases. Further, when crystals of a glass separate during firing, a softening point of residual glass may decrease, decomposition of binder components, which will be described later, cannot be performed sufficiently, and blackening may occur. Further, sinterability of the flat alumina particles may deteriorate in the glass ceramic body, and a compounding amount may be restricted. Moreover, control of separation of crystals is difficult, a dispersion may occur in the strength of glass ceramic body due to a dispersion in separation of crystals, or a warping or the like may occur due to changes in thermal expansion coefficient.

From such view points, the glass matrix formed in the firing process and constituted of glass particle components and alumina components which liquated from alumina particles is preferred not to generate crystallized glass. Specifically, the glass matrix is preferred to be non-crystalline, in which no peak of crystallized glass is detected by X-ray diffraction and the crystallinity is 0%.

However, when the glass ceramic body is manufactured in an environment where manufacturing conditions are sufficiently controlled, for example, when the glass ceramic body is manufactured while it is controlled so that separation of crystals occurs evenly in the stage after binder components are decomposed sufficiently in the process of manufacturing, the glass matrix may contain crystallized glass to a certain level. Specifically, the glass constituting the glass matrix may contain the crystallized glass as long as the crystallinity is 25% at most, and the crystallinity of the glass is preferably 20% or less, more preferably 15% or less. Note that adjustment of the crystallinity of the glass of the glass matrix is done by a method which will be described later.

Further, in this description, the open porosity of the glass ceramic body refers to an open porosity (%) calculated by using an Archimedes method according to JIS R1634. In the first aspect of the present invention, the open porosity of the glass ceramic body measured in this method is 5% or less. By setting the open porosity of the glass ceramic body to 5% or less, destruction due to stress concentration to a crack existing in the glass ceramic body can be suppressed, and the strength of the glass ceramic body can be raised to a sufficiently high level. The open porosity of the glass ceramic body is preferably 3% or less, more preferably 1% or less, particularly preferably 0%. Note that the open porosity of the glass ceramic body can be adjusted by sinterability due to the composition of the glass ceramic composition. Specifically, it is done by a method which will be described later.

In the glass ceramic body of the first aspect having the above structure, a three-point bending strength is preferably more than 400 MPa, more preferably 430 MPa or more, particularly preferably 450 MPa or more. Note that the three-point bending strength in this description refers to three-point bending strength that can be obtained by a method complying with JIS C2141.

Respective components contained in the glass ceramic composition for obtaining the glass ceramic body of the first aspect of the present invention will be described below.

(Flat Alumina Particles)

In the first aspect of the present invention, the glass ceramic composition contains flat alumina particles having a mean thickness of 0.4 μm or more, a mean major axis of 10 μm or less, and a mean aspect ratio of 3 to 18 by the ratio of 25 vol % or more relative to the total amount of the composition.

In general, the aspect ratio of a particle is defined as a value obtained by dividing the maximum diameter of the particle by the minimum diameter. Here, a flat particle like the flat alumina particles used in the present invention has a flat shape, and thus its minimum diameter corresponds to the length in a thickness direction of the particle, that is, a “thickness”. Further, the maximum diameter of the flat particle corresponds to a “major axis in a flat surface” of the particle. In this description, the minimum diameter of the flat particle is referred to as a “thickness” and the maximum diameter is simply referred to as a “major axis”. Therefore, the aspect ratio is a value obtained by dividing the major axis of the flat particle by its thickness. The mean thickness, the mean major axis, and the mean aspect ratio of the flat particle presented in this description refers to one calculated by averaging values of length measurement of 100 flat particles using a scanning electron microscope (SEM).

In the present invention, it is also possible to use one in which plural kinds of flat alumina particles whose mean thickness, mean major axis, and mean aspect ratio are in the above ranges are mixed, and in this case, a value obtained from the sum of values obtained by multiplying mean aspect ratios of the respective flat alumina particles and the ratio of existence thereof can be employed as the mean aspect ratio. Note that the same is true for the mean thickness and the mean major axis.

In the first aspect of the present invention, a high strength can be given to the glass ceramic body obtained by containing flat alumina particles having a mean thickness of 0.4 μm or more, a mean major axis of 10 μm or less, and a mean aspect ratio of 3 to 18 by 25 vol % or more.

The mechanism of destruction of the glass ceramic body is known such that a crack existing in a surface of the glass ceramic body becomes a stress concentration source, and the destruction occurs by the progress of this crack. On the other hand, by mixing anisotropic materials in the glass ceramic body, it is possible to increase a destruction strength by deflecting the direction of the crack to proceed, that is, dispersing the stress. However, when the destruction strength of the anisotropic material itself is low at this time, the crack proceeds by destruction of the anisotropic material itself, and the high strength cannot be given. In the first aspect of the present invention, the high strength can be given to the glass ceramic body by using the flat alumina particles having the above mean thickness, mean major axis, and mean aspect ratio.

When the mean thickness of the flat alumina particles is 0.4 μm or more, even when a surface vicinity portion thereof liquates into the molten glass during firing and they become flat alumina particles reduced in size after firing, the strength of itself is sufficient, and strength of the glass ceramic body can be maintained at a sufficiently high level.

Further, when the mean major axis of the flat alumina particles is 10 μm or less, glass particles and components derived from liquated alumina can be dispersed evenly in the glass matrix in the obtained glass ceramic body.

When the mean aspect ratio of the flat alumina particles is three or more, even when they are flat alumina particles reduced in size after firing, stress extension at a time of destruction of the glass ceramic body can be deflected, and strength of the glass ceramic body can be raised to a sufficiently high level. On the other hand, when the mean aspect ratio is 18 or less, glass particles and components derived from liquated alumina can be dispersed evenly in the glass matrix.

Further, by setting the content of the flat alumina particles relative to the total amount of the glass ceramic composition to 25 vol % or more, strength of the glass ceramic body can be raised to a sufficiently high level. When the content of the flat alumina particles is large, it is possible that bubbles remain in the glass ceramic body due to decrease in sinterability of the glass ceramic body and the strength decreases. The flat alumina particles can be contained in the range that makes the open porosity be 5% or less in the obtained glass ceramic body. From such an aspect, the content of the flat alumina particles is preferably 53 vol % or less, more preferably 50 vol % or less relative to the total amount of the glass ceramic composition. Note that for the sinterability of the glass ceramic body, the open porosity can be presented as an index. The provision of the open porosity in the glass ceramic body of the first aspect can be achieved by thus setting the content of the flat alumina particles in the glass ceramic composition to the above range.

As the flat alumina particles, ones having a mean thickness of 0.4 μm or more, a mean major axis of 6 μm or less, and a mean aspect ratio of 3 to 15 are preferred, and ones having a mean thickness of 0.5 μm or more, a mean major axis of 5 μm or less, and a mean aspect ratio of 4 to 10 are more preferred. The content of the flat alumina particles relative to the total amount of the glass ceramic composition is preferably 28 vol % or more, more preferably 30 vol % or more.

Examples of the flat alumina particles include α-alumina type, γ-alumina type, δ-alumina type, θ-alumina type, and the like depending on the type of crystal phase. In the present invention, the α-alumina type whose crystal phase has a corundum type structure is used preferably.

In the present invention, as the flat alumina particles, for example, flat alumina particles obtained by thermally treating flat boehmite particles obtained by hydrothermal synthesis of aluminum hydroxide are preferably used.

To obtain such flat boehmite particles, basically, a method can be employed such that a reactive material containing aluminum hydroxide and water are charged in an autoclave and pressure heated, hydrothermal synthesis is performed without stirring or with low stirring, and an obtained reactive product is washed, filtered, and dried.

When the flat boehmite particles are manufactured, preferably, various additives and reaction conditions are adjusted to adjust flat boehmite particles of the mean thickness, the mean major axis, and the mean aspect ratio so as to make it the same size as the flat alumina particles used in the present invention. Alternatively, as necessary, the flat boehmite particles may be classified to obtain flat boehmite particles of a desired size.

Next, the flat alumina particles can be obtained by firing the flat boehmite particles obtained above at a predetermined temperature. To obtain flat alumina particles having a crystal structure of α-alumina type, the flat boehmite particles are fired in the range of 1100° C. to 1500° C. When it is lower than 1100° C., it is difficult to obtain flat alumina particles having a crystal structure with 80% or more of the α crystallization degree obtained as follows is. When it exceeds 1500° C., sintering proceeds among alumina particles, and the flat shape may be impaired.

The α crystallization degree indicating the ratio of crystal phases which shifted to α-alumina type can be calculated with a formula (2) from a peak height (I_{25.6}) of an alumina α phase (012 plane) appearing at the position of 2θ=25.6° and peak heights (I₄₆) of a γ phase, η phase, χ phase, κ phase, θ phase, and δ phase appearing at the position of 2θ=46° from an X-ray diffraction spectrum of the flat alumina particles obtained by using a powder X-ray diffraction apparatus using a CuKα ray as a characteristic X ray.

α crystallization degree=I_{25.6}/(I_{25.6}+I₄₆)×100(%) (2)

The α crystallization degree in the flat alumina particles used in the present invention is preferably 80% or more, more preferably 90% or more, furthermore preferably 95% or more, particularly preferably 100%. When it is less than 80%, the strength of the flat alumina particles themselves is weak, and it is possible that the strength as the glass ceramic body decreases.

The firing time is preferably 1 to 4 hours, further preferably 1.5 to 3.5 hours. When it is less than one hour, the firing is insufficient and it is difficult to obtain even α-alumina type particles. Further, aluminization mostly completes within four hours, and thus firing over four hours is not economical.

In this method, the flat alumina particles having a mean thickness of 0.4 μm or more, a mean major axis of 10 μm or less, and a mean aspect ratio of 3 to 18 used in the present invention are obtained. Note that the flat alumina particles used in the present invention may be obtained by performing an operation of classification with respect to flat alumina particles obtained without performing size adjustment in the stage of manufacturing the flat boehmite particles, so as to make the mean thickness, the mean major axis, and the mean aspect ratio be in the above ranges.

As the method for manufacturing the flat alumina particles, the above method is exemplified as a preferred one, but it is not necessarily limited to this method. A publicly known manufacturing method can be employed appropriately as long as it can allow obtaining a predetermined shape.

(Glass Particles)

The glass particles are not particularly limited as long as they soften and unite with alumina components which liquate from the flat alumina particles during firing, into a glass with a crystallinity of 25% or less, and then form a glass matrix surrounding the flat alumina particles. The crystallinity is, as described above, preferably 20% or less, more preferably 15% or less. In particular, preferably, the glass matrix does not have a crystallized glass, that is, is amorphous.

In a first aspect of the present invention, the glass composition of the glass matrix is constituted of glass particle components and alumina components which liquate from the flat alumina particles. The alumina in the glass composition of the glass matrix is the sum of alumina contained in the glass composition of glass particles and alumina which liquates from the flat alumina particles, and the components other than alumina are components of glass particles. The components excluding alumina are components of glass particles. The components excluding alumina (Al₂O₃) constituted only of components derived from glass particles in the glass composition of the glass matrix will be described below.

In the glass composition of the glass matrix of the glass ceramic body of the first aspect having the above structure, in order to make the range of the crystallinity be the above range, as the composition excluding Al₂O₃, an SiO₂—B₂O₃ based glass is preferred, an SiO₂—B₂O₃-MO based (M: alkaline earth metal) glass is more preferred, and an SiO₂—B₂O₃—CaO based glass is particularly preferred.

The contents of respective components when the composition excluding Al₂O₃ is 100% in mole percentage based on oxides in the glass composition of the glass matrix will be described below. In a glass which is SiO₂—B₂O₃—CaO based in the composition excluding Al₂O₃, in order to make the range of the crystallinity be in the above range, CaO is preferably 10% or more. Similarly, the content of B₂O₃ in the SiO₂—B₂O₃—CaO based glass is preferably 13% or more, and a total content of SiO₂, B₂O₃, and CaO is preferably 75% or more.

More specifically, as the SiO₂—B₂O₃—CaO based glass, a composition is preferred which contains 40 to 68% of SiO₂, 13 to 20% of B₂O₃, 10 to 40% of CaO, and 0 to 10% in total of at least one selected from the group consisting of Na₂O and K₂O, in which a total content of SiO₂, B₂O₃, and CaO is 75% or more, which are expressed as mol %.

A more preferred composition contains 44 to 64% of SiO₂, 15 to 18% of B₂O₃, 15 to 37% of CaO, and 0 to 5% in total of at least one selected from the group consisting of Na₂O and K₂O, in which a total content of SiO₂, B₂O₃, and CaO is 85% or more.

Note that the glass may contain 0 to 10% in total of at least one selected from the group consisting of MgO, SrO, and BaO.

Note that in the glass composition of the glass matrix, in order to make the range of the crystallinity be in the above range, the content of Al₂O₃ is preferably 3 to 15% in mole percentage based on oxides. This amount is an amount sufficiently satisfied by Al₂O₃ which liquated from the flat alumina particles. Therefore, the glass composition of the glass particles constituting the glass ceramic composition may contain Al₂O₃, but an amount keeping the above range is preferred as the glass composition of the glass matrix to which Al₂O₃ which liquated from the flat alumina particles are added.

In the first aspect of the present invention, the glass particles constituting the glass ceramic composition preferably has a glass composition as described above with respect to the composition excluding Al₂O₃ and the content of Al₂O₃. As such a glass composition in glass particles, specifically, a composition is exemplified which contains 40 to 65% of SiO₂, 13 to 18% of B₂O₃, 10 to 38% of CaO, 0 to 10% of Al₂O₃, 0 to 10% in total of at least one selected from the group consisting of MgO, SrO, and BaO, 0 to 10% in total of at least one selected from Na₂O and K₂O, in which a total content of SiO₂, B₂O₃, and CaO is 70% or more, which are expressed as mol % based on oxides.

The composition of the glass particles will be described below. Note that “%” in the description of the glass composition represents a mol % expression based on oxides unless otherwise noted in particular.

SiO₂ becomes a network former of the glass, and is an essential component for increasing chemical durability, particularly acid resistance. When the content of SiO₂ is 40% or more, the acid resistance is sufficiently ensured. Further, when the content of SiO₂ is 65% or less, a glass softening point (hereinafter denoted by “Ts”) and a glass transition point (hereinafter denoted by “Tg”) are adjusted in a moderate range without increasing excessively. The content of SiO₂ is preferably 43 to 63%.

B₂O₃ is an essential component that becomes a network former of the glass. When the content of B₂O₃ is 13% or more, Ts is adjusted in a moderate range without increasing excessively, and stability of glass is kept sufficiently. On the other hand, when the content of B₂O₃ is 18% or less, a stable glass is obtained, and chemical durability is sufficiently ensured. The content of B₂O₃ is preferably 15 to 17%.

CaO is an essential component compounded for improving wettability with the glass and the flat alumina particles, and ensuring sinterability of the glass matrix in the obtained glass ceramic body. When the content of CaO is 10% or more during firing, the alumina which liquates from the flat alumina particles can be dispersed easily in the molten glass, and sinterability of the glass matrix can be ensured sufficiently. Further, during firing, accompanying that the alumina which liquated from the flat alumina particles disperse in the molten glass derived from glass particles, the alumina content in the composition of the molten glass increases, and the softening point decreases. Thus, fluidity of the flat alumina particles increases, and rearrangement of the flat alumina particles in the glass matrix is facilitated.

Specifically, even when a dispersion in existence ratio or orientation of the flat alumina particles exists in the state of the green sheet before firing, a glass ceramic body in which rearrangement of the flat alumina particles took place during firing as described above can be obtained. Therefore, such as a dispersion in strength of the glass ceramic body, and for example, a dispersion in warping of a substrate when the glass ceramic body is a substrate can be suppressed. When the content of CaO is 38% or less, crystallization of glass of the glass matrix can be suppressed. The content of CaO is preferably 13 to 35%, more preferably 15 to 35%.

SiO₂ and B₂O₃ as a network performer and CaO which improves wettability with the flat alumina particles are contained by the above respective ratios, and are compounded so that their total content is 70% or more. When the total content is 70% or more, stability and chemical durability of the glass can be ensured sufficiently and wettability with the flat alumina particles improves, and strength of the glass ceramic body can be ensured sufficiently. The total content of SiO₂, B₂O₃, and CaO is preferably 75% or more, more preferably 80% or more.

Al₂O₃ contained arbitrarily in the glass particles is a component that becomes a network former of the glass, and is compounded for increasing stability and chemical durability of the glass. Here, as described above, in the glass ceramic body of the first aspect, the composition of the glass of the glass matrix contains Al₂O₃ which liquated from the flat alumina particles in the process of manufacturing. In the glass composition of the glass matrix, Al₂O₃ is a component which is always contained, but Al₂O₃ in the glass particles is an arbitrary component. When the content of Al₂O₃ exceeds 10% in the glass particles, it may impair sinterability of the glass matrix in the vicinity of an interface with the flat alumina particles. The content of Al₂O₃ of the glass particles is preferably 0 to 7%.

Alkaline earth metal oxides other than CaO such as MgO, SrO, BaO are also components which can improve wettability with the flat alumina particles while suppressing crystallization of the glass. Further, they are also useful for adjusting Ts and Tg. At least one selected from the group consisting of MgO, SrO, and BaO is a component added arbitrarily as an alkaline earth metal oxide. By compounding these alkaline earth metal oxides by a content of 10% or less, Ts and Tg can be adjusted in a moderate range without decreasing excessively.

The alkaline metal oxides such as K₂O and Na₂O are components which decreases Ts and Tg and can suppress phase splitting of the glass, and is a component preferred to be added. When the total content of at least one selected from the group consisting of K₂O and Na₂O is 10% or less, it can serve the above function sufficiently without leading to decrease in chemical durability, particularly acid resistance, or decrease in electric insulating performance. The total content of K₂O and Na₂O is preferably 1 to 8%, more preferably 1 to 6%.

In the first aspect of the present invention, among such glass particles, glass particles are preferred which have a composition containing, in mole percentage based on oxides, 43 to 63% of SiO₂, 15 to 17% of B₂O₃, 13 to 35% of CaO, 0 to 7% of Al₂O₃, and 1 to 6% in total of at least one selected from the group consisting of Na₂O and K₂O, in which the total content of SiO₂, B₂O₃, and CaO is 75% or more.

Note that the glass particles are not necessarily limited to ones constituted of the above components, and can contain other components within a range satisfying characteristics such as Ts and Tg. When other components are contained, the total content of them is preferably 10% or less.

According to an application of the obtained glass ceramic body, the glass composition of the glass particles may also be adjusted appropriately in a form that satisfies the performance required in this application. For example, when the glass ceramic body is used for a substrate for mounting a light emitting element, it is required to increase reflectivity of light. In such cases, a glass composition may be used which causes the difference between a refractive index of the glass matrix and a refractive index of the flat alumina particles to be large, for example, 0.15 or more, to make scattering in the interface between them be favorable and increase reflectivity.

Such a refractive index of the glass can be calculated by using Appen's coefficient. Additive properties (coefficients) of respective components in a silicate glass containing alkali are presented in Table 1. (Source: A. A. Appen: Chemistry of Glass, Nisso Tsushinsha (1974) p. 318)

TABLE 1

| Component | Additive Property |
|---|---|
| SiO₂ | 1.46~1.48 |
| B₂O₃ | 1.46~1.71 |
| Al₂O₃ | 1.52 |
| MgO | 1.61 |
| CaO | 1.73 |
| SrO | 1.78 |
| Na₂O | 1.59 |
| K₂O | 1.58 |
| TiO₂ | 2.13 |
| ZrO₂ | 2.2 |
| LiO | 1.7 |
| ZnO | 1.71 |

The glass particles used in the present invention is obtained by compounding and mixing glass raw materials to make a glass as described above, a glass is produced by a melting method, and the obtained glass is pulverized by a dry grinding method or a wet grinding method. In the case of the wet grinding method, water or ethyl alcohol is used preferably as a solvent. The grinding may be performed using a pulverizer such as a roll mill, a ball mill, or a jet mill, for example.

A 50% particle diameter (D₅₀) of glass particles is preferred to be 0.5 to 2 μm. When D₅₀ of the glass particles is less than 0.5 μm, the glass particles aggregate easily and become difficult to handle, and moreover they become difficult to be evenly dispersed. On the other hand, when D₅₀ of the glass particles exceeds 2 μm, there may occur increase in Ts or insufficient sintering. The particle diameter may be adjusted by, for example, performing classification as necessary after pulverization. Note that D₅₀ of the powder presented in this description is obtained by a particle diameter measuring apparatus (made by Nikkiso, product name: MT3100II) by a laser diffraction/scattering method.

(Glass Ceramic Composition)

The glass ceramic composition used for obtaining the glass ceramic body of the first aspect of the present invention contains the flat alumina particles and the glass particles described above. The ratio of the flat alumina particles relative to the total amount of the glass ceramic composition is 25 vol % or more, preferably 28 vol % or more, more preferably 30 vol % or more. On the other hand, the ratio of the flat alumina particles, although they can be contained in a range that makes the open porosity of the glass ceramic body after firing be 5% or less, preferably it is 53 vol % or less, more preferably 50 vol % or less.

Here, the glass ceramic composition may contain ceramic particles other than the flat alumina particles according to an application of the obtained glass ceramic body in a range that does not impair effects of the present invention. Specifically, examples include alumina particles with a mean aspect ratio of less than 3 (hereinafter described as irregular alumina particles), ceramic particles such as silica, zirconia, titania, magnesia, mullite, aluminum nitride, silicon nitride, silicon carbide, forsterite, and cordierite, for which a shape such as flat or irregular is of no object in particular. Among others, use of zirconia particles is preferred when high reflectivity is required as in the substrate for mounting a light emitting element.

A compounding amount of such ceramic particles other than the flat alumina particles in the glass ceramic composition just needs to be an amount that does not impair effects of the present invention, specifically, an amount of 15 vol % or less, more preferably 13 vol % or less relative to the total amount of the glass ceramic composition. Here, when the irregular alumina particles are used in addition to the flat alumina particles, the composition of the glass constituting the glass matrix contains alumina components liquated from both the flat alumina particles and the irregular alumina particles.

The content of the glass particles in the glass ceramic composition is a value resulted from subtracting the total amount of the flat alumina particles and the other ceramic particles from 100. A preferred content is 47 to 70 vol %, more preferably 50 to 60 vol %.

(Glass Ceramic Body)

The glass ceramic body of the first aspect is obtained by forming such a glass ceramic composition into a green sheet and thereafter firing it. As a method for forming the glass ceramic composition into a green sheet, the usual method for forming a glass ceramic composition constituted of glass particles and ceramic particles into a green sheet can be applied without any particular limitation.

Specifically, first, a binder and a plasticizer, a solvent, a dispersant, and/or the like as necessary are added to the glass ceramic composition to prepare a slurry. Note that in the slurry, all the components other than the glass ceramic composition will be lost during subsequent performed firing.

As the binder, for example, polyvinyl butyral, acrylic resin, or the like can be used preferably. As the plasticizer, for example, dibutyl phthalate, di-2-ethylhexyl phthalate, dioctyl phthalate, butyl benzyl phthalate, or the like can be used. Further, as the solvent, an aromatic solvent such as toluene or xylene, an alcohol solvent such as 2-propanol or 2-butanol can be used. Preferably, the aromatic solvent and the alcohol solvent are mixed and used. Moreover, a dispersant may be used together.

Further, as the compounding amount of respective components in the slurry, 5 to 15 parts by mass of the binder, 1 to 5 parts by mass of the plasticizer, 2 to 6 parts by mass of the dispersant, and 50 to 90 parts by mass of the solvent relative to 100 parts by mass of the glass ceramic composition are preferred.

Preparation of the slurry is by, for example, adding the glass ceramic composition to a mixed solvent obtained by mixing the solvent with a dispersant as necessary, and stirring them by a ball mill using ZrO₂ as a medium. A vehicle obtained by dissolving a binder in a solvent is added thereto, which is stirred with a stirrer having a propeller and thereafter filtered using a mesh filter. At this time, bubbles confined inside can be removed by stirring while vacuuming.

Next, the obtained slurry is formed in a sheet shape by applying it on a PET film, on which a release agent is applied, by using a doctor blade for example, and dried to thereby produce a green sheet. Note that the method for forming the green sheet from the slurry may be a roll forming method. In any method, during formation of the green sheet, the flat alumina particles are oriented in a direction in which their individual thickness directions are substantially perpendicular to a surface direction of the green sheet.

For example, in the case of application by a doctor blade method, the slurry passes through a gap formed by a tip of blade part of a doctor blade apparatus and a surface of the PET film, and thus the flow (flow line) of the slurry is along a carrying direction of the PET film. At this time, the flat alumina particles dispersed in the slurry also pass through the gap along the flow of the slurry. Accordingly, the flat alumina particles in the green sheet are oriented so that their flat surface directions are substantially parallel with the surface direction of the green sheet. Note that when the flat surfaces have, for example, a long length direction and a short length direction like a rectangle does, long length directions, that is, major axis directions of flat alumina particles become substantially parallel with a formation direction of the doctor blade method.

Note that formation of the green sheet is normally performed with a flow in a certain direction in any method, and thus orientation of flat alumina particles in the green sheet is performed similarly in any other method than the doctor blade method, such as a roll forming method. In the present invention, the doctor blade method is preferred in that it can stably obtain a green sheet in which the flat alumina particles are oriented in the same direction at high ratio.

One green sheet may be fired as a single layer to make the glass ceramic body, or plural green sheets may be layered and fired to make the glass ceramic body. When plural green sheets are layered, preferably, respective green sheets are layered so that the formation directions by the doctor blade method, the roll forming method, or the like matching, so as to obtain higher strength in the obtained glass ceramic body. However, in this case, as long as strength of a certain degree or more, for example, strength over 400 MPa by three-point bending strength can be obtained in the obtained glass ceramic body, the green sheets may be layered as necessary so that their formation directions are orthogonal alternately. When the plural green sheets are layered, they are integrated by thermocompression bonding.

Thereafter, degreasing for decomposing and removing the components other than the glass ceramic composition such as the binder in the green sheet is performed, and subsequently the glass ceramic composition is sintered to obtain the glass ceramic body.

The degreasing is performed by, for example, retaining at a temperature of 500 to 600° C. for 1 to 10 hours. When the degreasing temperature is lower than 500° C. or the degreasing time is less than one hour, it is possible that the binder and so on are not decomposed and removed sufficiently. When the degreasing temperature is about 600° C. and the degreasing time is about 10 hours, the binder and so on can be removed sufficiently, but exceeding this time length may conversely decrease productivity and the like.

The firing temperature is adjusted corresponding to Ts of the glass particles contained in the glass ceramic composition and the crystallization temperature of the glass constituting the glass matrix, which contains glass particle components and alumina components and so on which liquated from the flat alumina particles and the arbitrarily added irregular alumina particles. Normally, a temperature equal to or lower than the crystallization temperature of the glass of such a glass matrix and higher than Ts of the glass particles by 0 to 200° C., preferably Ts+50° C. to Ts+150° C., is set to the firing temperature.

For example, when the above-described glass particles which allows suppressing the crystallinity in the glass matrix to 25% or less are used, a temperature of 800 to 900° C. can be set to the firing temperature, and a firing temperature of 830 to 880° C. is particularly preferred. The firing time can be adjusted to about 20 to 60 minutes. When the firing temperature is lower than 800° C. or the firing time is less than 20 minutes, it is possible that a fine sintered compact cannot be obtained. When the firing temperature is about 900° C. and the firing time is about 60 minutes, a sufficiently fine one can be obtained, but when it exceeds that, it is possible that productivity and the like decrease conversely.

Upon operating such firing, only the glass particles in the green sheet melt, and the molten glass fills gaps among the flat alumina particles. At this time, the vicinity of a surface of a flat alumina particle liquates from an interface with the molten glass and diffuses into the glass components. By the alumina diffusing into the molten glass, the softening point of the glass lowers, fluidity of the flat alumina particles increases, and the sintering proceeds while rearrangement of the flat alumina particles is facilitated. At this time a firing shrinkage ratio in the surface direction of the green sheet is preferably 6 to 20%. When the shrinkage ratio in the surface direction is less than 6%, rearrangement of particles have not proceeded, and when the glass ceramic body is a substrate, warping of the substrate may occur. When it exceeds 20%, fluidity of the glass is high, the dispersion occurs in the existence ratio of the flat alumina particles in the glass ceramic, and the strength may also disperse. When the firing shrinkage ratio in the surface direction is 6 to 20%, the shrinkage ratio in the thickness direction becomes about 10 to 30%.

Further, the flat alumina particles shrink in size in its entirety while substantially keeping its aspect ratio during firing. Further, during firing, the green sheet shrinks in dimensions in thickness direction and vertical and horizontal direction, but the state that the flat alumina particles are oriented substantially parallel with the surface direction of the green sheet is maintained. Therefore, the obtained glass ceramic body of the first aspect has a structure in which the flat alumina particles whose major axis directions are oriented substantially parallel with the surface direction constituting the main surface when it is the green sheet are dispersed in the glass matrix, and has sufficient strength. As described above, the strength of the glass ceramic body of the first aspect is, for example, preferably more than 400 MPa, more preferably 430 MPa or more, particularly preferably 450 MPa or more by three-point bending strength.

The open porosity of the glass ceramic body of the first aspect of the present invention is 5% or less. The open porosity of the glass ceramic body is preferably 3% or less, more preferably 1% or less, particularly preferably 0%. By having the open porosity of the glass ceramic body in the above ranges, the strength of the glass ceramic body can be increased to a sufficiently high level. Further, when pores exist in the glass ceramic body, plating liquid easily enters the pores in a plating step, which can cause change of color. Therefore, by having the open porosity of the glass ceramic body in the above ranges, reliability with respect to change of color can be increased while securing strength.

Note that when particles that can suppress generation of crystallized glass to be low by the temperature range during firing, specifically, particles that can suppress the crystallinity to 25% or less are used as the glass particles, a stable firing state can be ensured, and a dispersion of strength due to separation of crystals can be suppressed. Moreover, the glass ceramic body of the first aspect of the present invention can be obtained by firing the green sheet without binding, particularly by a binding layer or the like. Therefore, when green sheets having different shapes are layered and sintered, although they shrink slightly, a glass ceramic body of their layered shape can be obtained. In other words, it is a glass ceramic body having a high degree of flexibility in shape which can correspond to a three-dimensional shape.

Here, among the glass ceramic bodies of the first aspect, the glass ceramic body obtained by firing the single layer of green sheet, or layering the plural layers of green sheets in the same formation direction and firing them, is a glass ceramic body which substantially corresponds to a structure of a glass ceramic body of a second aspect below in a cross section taken along a thickness direction and substantially parallel with the formation direction of the green sheet.

[Glass Ceramic Body of a Second Aspect]

The glass ceramic body of a second aspect of the present invention is a glass ceramic body in which flat alumina particles are dispersed in a glass matrix, wherein the glass matrix is constituted of a glass with a crystallinity of 25% or less, the flat alumina particles are dispersed in the glass matrix in a direction in which individual thickness directions thereof are substantially perpendicular to a surface direction of one of surfaces of the glass ceramic body, and a total cross-sectional area of the flat alumina particles, having a cross section with a thickness of 0.2 μm or more, a maximum diameter of 8 μm or less, and an aspect ratio in a range of 3 to 18 in one of cross sections along the thickness directions of the flat alumina particles in the glass ceramic body, is 20% or more relative to a total area of the cross section, and an open porosity of the glass ceramic body is 5% or less.

In the glass ceramic body of the second aspect of the present invention, in one of cross sections along the thickness directions of the flat alumina particles contained as described above, the ratio occupied by flat alumina particles with a cross section having the above specific shape in the total cross-sectional area thereof is prescribed as 20% or more. When the shape of a cross section of a flat alumina particle appearing in the above cross section of the glass ceramic body is mentioned, in this description, the “thickness” is equivalent to the thickness of the flat alumina particle since this cross section is along the thickness direction of the flat alumina particle. On the other hand, the “maximum diameter” denotes a maximum diameter of a flat alumina particle cross section in this cross section, and does not necessarily match the major axis of the flat alumina particle. This will also be hereinafter referred to as “cross-sectional maximum diameter” as necessary. Moreover, the “aspect ratio” refers to a value resulted from dividing this cross-sectional maximum diameter by the thickness, and will also be hereinafter referred to as a “cross-sectional aspect ratio” as necessary.

The glass ceramic body of the second aspect of the present invention is, for example, a glass ceramic body in the form surrounded by a combination of flat surfaces, and has a structure in which the flat alumina particles are dispersed in the glass matrix in a direction in which individual thickness directions thereof are substantially perpendicular to a surface direction of one of the flat surfaces, that is, individual particles are in a substantially same direction as the thickness direction. Here, the substantially same direction means that it can be visually recognized as the same direction when observed by magnifications that allow recognizing the mode of the flat alumina particles with a stereoscopic microscope or the like.

In the glass ceramic body of the second aspect, it will suffice when the above prescribed structure is satisfied in one of cross sections taken along the thickness directions of flat alumina particles, and it is not always necessary to satisfy the above prescribed structure in all the cross sections taken along the thickness directions of the flat alumina particles. This is because when at least a certain cross section satisfies the prescription, this glass ceramic body has sufficient strength.

Here, in the glass ceramic body of the second aspect, preferably, not only the orientation of the flat alumina particles is substantially the same as the thickness direction, but also directions of the flat surfaces are substantially the same. Then, a glass ceramic body that satisfies the above prescription in a cross section substantially parallel with the major axis direction of the flat alumina particles is preferred.

In the second aspect of the present invention, by making the glass ceramic body having the above structure, a glass ceramic body having a sufficiently high strength and having a high degree of flexibility in shape which can correspond to a three-dimensional shape is made.

In the glass ceramic body of the second aspect of the present invention, the crystallinity of the glass constituting the glass matrix which is measured and calculated similarly to that in the first aspect is 25% or less. In the glass ceramic body of the second aspect of the present invention, particularly the glass of the glass matrix is preferably amorphous with a crystallinity of 0% due to the same reasons as the first aspect, but a crystallized glass may be contained up to the crystallinity of 25%, and the crystallinity of the glass is preferably 20% or less, more preferably 15% or less. Note that the crystallinity of the glass of the glass matrix can be adjusted similarly to the glass ceramic body of the first aspect.

The open porosity of the glass ceramic body of the second aspect of the present invention is 5% or less. By having the open porosity of the glass ceramic body of 5% or less, strength of the glass ceramic body can be raised to a sufficiently high level. The open porosity of the glass ceramic body is preferably 3% or less, more preferably 1% or less, particularly preferably 0%. Note that the open porosity of the glass ceramic body can be adjusted similarly to the glass ceramic body of the first aspect.

Further, the three-point bending strength of the glass ceramic body of the second aspect is preferably more than 400 MPa, more preferably 430 MPa or more, particularly preferably 450 MPa or more.

The glass ceramic body of the second aspect will be described below with reference to drawings.

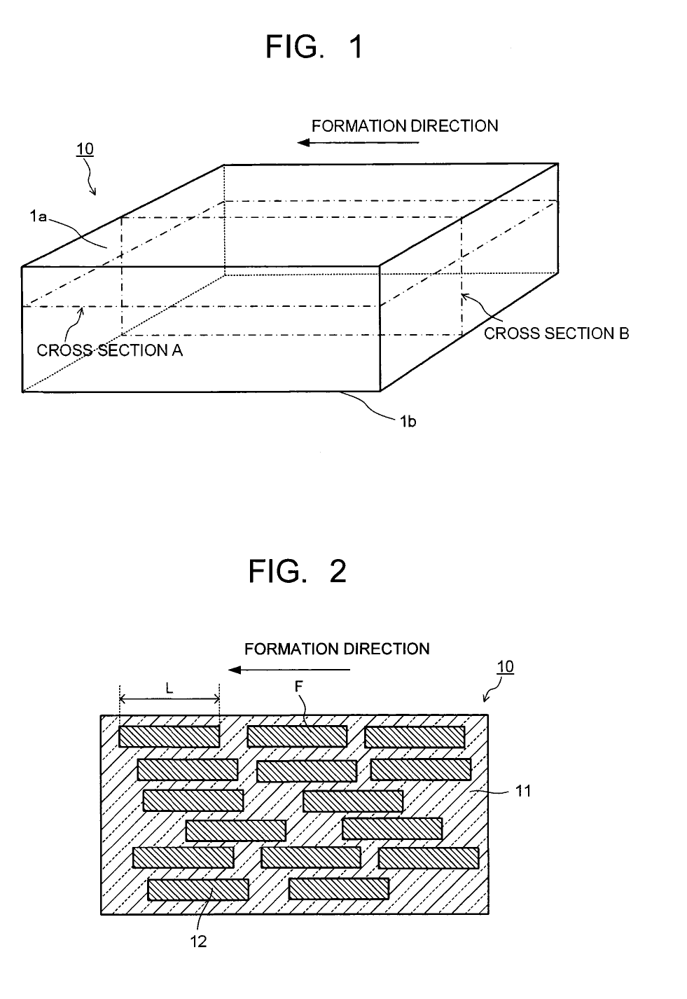

FIG. 1 is an exterior view illustrating one embodiment of the glass ceramic body of the second aspect of the present invention. The glass ceramic body illustrated in FIG. 1 is, for example, a glass ceramic body 10 formed in a plate shape and having a structure in which a formation direction of the glass ceramic body matches a formation direction illustrated in FIG. 1, and flat alumina particles (not illustrated) are dispersed in a glass matrix (not illustrated). Here, the formation direction of the glass ceramic body is, for example, the formation direction of the doctor blade method when the glass ceramic body is obtained by firing a green sheet formed by the doctor blade method. The same is true for the formation direction of the glass ceramic body obtained when the green sheet is formed by a different forming method.

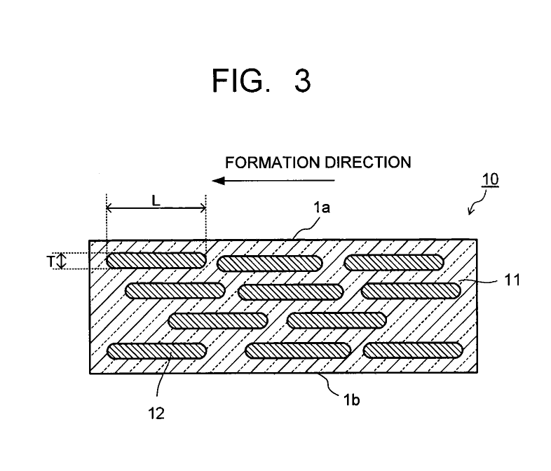

FIG. 2 is a schematic cross-sectional view in a cross section A of the glass ceramic body 10 illustrated in FIG. 1, that is, a cross section taken along a surface parallel with main surfaces 1a, 1b of the glass ceramic body 10. FIG. 2 schematically illustrates a state that, in the glass ceramic body 10 containing flat (schematically represented as a rectangular plate) alumina particles 12, the flat alumina particles 12 are oriented with their major axis (denoted by “L” in FIG. 2) directions match the formation direction in the glass matrix 11. FIG. 3 is a schematic cross-sectional view in a cross section B of the glass ceramic body 10 in a relation of perpendicular direction with the cross section of FIG. 2, and schematically illustrates a cross section which is along a thickness (denoted by “T” in FIG. 3) direction of the flat alumina particles 12 in the glass ceramic body 10 illustrated in FIG. 1, and which is substantially parallel with the major axis (L) direction of the flat alumina particles 12, that is, the formation direction.

The glass ceramic body 10 illustrated in FIG. 1 to FIG. 3 is in the form of plate shape, and the flat alumina particles 12 disperse in the glass matrix 11 in a direction in which individual thicknesses (T) directions are substantially perpendicular to the surface direction of the main surfaces 1a, 1b of the glass ceramic body 10, which are illustrated as located vertically in FIG. 1 and FIG. 3. In other words, as illustrated in FIG. 2, the flat alumina particles 12 are dispersed so that flat surfaces (F) of respective particles are parallel with the main surfaces of the glass ceramic body 10. Note that the thickness (T) directions of the flat alumina particles 12 are, for example, up and down directions in the view in the case illustrated in FIG. 3, and a flat direction (that is, length direction) is a direction (left and right direction in FIG. 3) perpendicular to this thickness direction.

The glass matrix 11 is not particularly limited as long as the crystallinity of glass is 25% or less, but one in which the crystallinity of glass is 20% or less is preferred, 15% or less is more preferred. As the glass constituting the glass matrix 11, particularly one which is not crystallized after firing, that is, amorphous one is preferred as described above. Advantages of the glass matrix being amorphous are the same as in the case of the glass ceramic body of the first aspect.

In the glass ceramic body of the second aspect of the present invention, when the cross section as in FIG. 3 is observed with a stereoscopic microscope, the flat alumina particles 12 are dispersed in the glass matrix 11 so that the individual thicknesses (T) are substantially perpendicular to the surface directions of the main surfaces 1a, 1b of the glass ceramic body 10, and hence the thickness directions are individually and substantially the same directions. Further, as described above, the cross section illustrated in FIG. 3 is substantially parallel with the major axis direction of the flat alumina particles 12, and the major axis (L) of the flat alumina particles 12 can be confirmed in this cross section. Therefore, in the cross section illustrated in FIG. 3, the cross-sectional maximum diameter of the flat alumina particles 12 corresponds to the major axis, and the cross-sectional aspect ratio corresponds to the aspect ratio.

The cross-section along the thickness directions of the flat alumina particles 12 in the glass ceramic body 10 illustrated in FIG. 3 matches the cross section along the thickness direction of the glass ceramic body 10. In the cross section along the thickness direction of the glass ceramic body 10, among the flat alumina particles 12, a total cross-sectional area of the flat alumina particles 12, having a cross section with a thickness (T) of 0.2 μm or more, a maximum diameter, a major axis (L) in this case, of 8 μm or less, and an aspect ratio in the range of 3 to 18 (hereinafter referred to as “flat alumina particles with the prescribed cross section”), is 20% or more relative to the total area of this cross section. Note that the ratio occupied by the total cross-sectional area of the flat alumina particles 12 with the prescribed cross section relative to the total area of the cross section of the glass ceramic body 10 (hereinafter referred to as “an area occupancy ratio of the flat alumina particles with the prescribed cross section”) is preferably 45% or less.

In the cross-section along the thickness directions of the flat alumina particles of the glass ceramic body, the flat alumina particles with the prescribed cross section are flat alumina particles which meet the conditions of having a cross section with a thickness of 0.2 μm or more, a cross-sectional maximum diameter of 8 μm or less, and a cross-sectional aspect ratio of 3 to 18. In such flat alumina particles with the prescribed cross section, by having a thickness of 0.2 μm or more, strength of the flat alumina particles themselves is sufficient, and strength of the glass ceramic body can be maintained to a sufficiently high level. Further, by having the cross-sectional maximum diameter of 8 μm or less, even dispersion into the glass matrix can be achieved. Regarding the cross-sectional aspect ratio, when it is 3 or more, extension of crack stress during destruction of the glass ceramic body is deflected and strength of the glass ceramic body 10 can be raised to a sufficiently high level, and when it is 18 or less, even dispersion into the glass matrix during manufacturing can be achieved.

In the glass ceramic body of the second aspect, by that the area occupancy ratio of such flat alumina particles with the prescribed cross section is 20% or more in one of cross sections along the thickness directions of the flat alumina particles in the glass ceramic body, strength of the glass ceramic body is at a sufficiently high level. Note that when the area occupancy ratio of the flat alumina particles with the prescribed cross section is high, strength may decrease due to decrease in sinterability of the glass ceramic body, and thus the area occupancy ratio is preferably 45% or less. Similarly to the glass ceramic body of the first aspect, an open porosity can be presented as an index for the sinterability of the glass ceramic body. The prescription of the open porosity in the glass ceramic body of the second aspect described above can be achieved by thus having the area occupancy ratio of the flat alumina particles with the prescribed cross section in the above range.

Here, the area occupancy ratio (%) of the flat alumina particles with the prescribed cross section in the cross section of the glass ceramic body can be calculated by measuring the thicknesses of the individual flat alumina particles and the cross-sectional maximum diameter in 100 μm² of a measurement cross section by using a scanning microscope (SEM) and an image analysis apparatus, obtaining the sum (μm²) of the cross sections of the flat alumina particles with the prescribed cross section, dividing it by 100 μm², and further multiplying it by 100.

FIG. 3 is a cross-sectional view schematically illustrating a cross section along the thickness directions of the flat alumina particles 12 in a typical glass ceramic body example in which the particles are dispersed in the glass matrix 11 in a direction in which the individual thickness directions of the flat alumina particles 12 are substantially perpendicular to a surface direction of one of surfaces of the glass ceramic body. In FIG. 3, the cross sections of all the flat alumina particles 12 satisfy the conditions of the prescribed cross section, but in the glass ceramic body of the second aspect, flat alumina particles existing in a cross section of the glass ceramic body need not always be the flat alumina particles with the prescribed cross section, and it suffices when the area occupancy ratio of the flat alumina particles with the prescribed cross section is 20% or more.

As described above, in the glass ceramic body of the second aspect, the area occupancy ratio of the flat alumina particles with the prescribed cross section is 20% or more in one of cross sections along the thickness directions of the flat alumina particles thereof. Further, the area occupancy ratio of the flat alumina particles with the prescribed cross section is preferably 45% or less. Note that in such a cross section, a total cross-sectional area of cross sections of alumina particles not satisfying the conditions of the flat alumina particles 12 with the prescribed cross section and cross sections of other ceramic particles which will be described later is preferably 25% or less, more preferably 20% or less, particularly preferably 15% or less relative to the entire cross sectional area of the glass ceramic body.

Note that in the cross section in which the area occupancy ratio of the flat alumina particles with the prescribed cross section is 20% or more, preferably, a mean thickness of the flat alumina particles with the prescribed cross section is 0.25 μm or more, a mean cross-sectional maximum diameter is 5 μm or less, and a mean cross-sectional aspect ratio is 3 to 18.

Further, in the glass ceramic body of the second aspect, although it suffices that the above prescription is achieved in one of cross sections along the thickness directions of the flat alumina particles, a glass ceramic body is preferred in which the area occupancy ratio of the flat alumina particles with the prescribed cross section is measured and calculated for each of arbitrary plural cross sections, for example, 10 to 20 cross sections along the thickness directions of the flat alumina particles, and an average thereof is 20% or more. For example, in the glass ceramic body 10 illustrated in FIG. 1 to FIG. 3, as the arbitrary 10 to 20 cross sections along the thickness directions of the flat alumina particles, cross sections taken along a flat surface which is along the thickness directions of the flat alumina particles 12 as illustrated in FIG. 3 and parallel with the major axis of the flat alumina particles 12 are normally chosen.

Note that also when the area occupancy ratio of the flat alumina particles with the prescribed cross section is thus measured and calculated in plural cross sections, the mean thickness, the mean cross-sectional maximum diameter, and the mean cross-sectional aspect ratio of the flat alumina particles are preferred to be in the above ranges.

Note that as described above, strength of the glass ceramic body of the second aspect is preferably more than 400 MPa, more preferably 430 MPa or more, particularly preferably 450 MPa or more by three-point bending strength. Such strength can be achieved sufficiently when the structure of the glass ceramic body is the structure of the second aspect of the present invention.

Here, the glass ceramic body of the second aspect may contain ceramic particles other than the flat alumina particles depending on an application of an obtained glass ceramic body within the range that does not impair effects of the present invention. Specifically, examples include irregular alumina particles, ceramic particles such as silica, zirconia, titania, magnesia, mullite, aluminum nitride, silicon nitride, silicon carbide, forsterite, and cordierite, for which a shape such as flat or irregular is of no object in particular. Among others, use of zirconia particles is preferred when high reflectivity is required as in the substrate for mounting a light emitting element.

A compounding amount of such the irregular alumina particles and ceramic particles other than alumina particles in the glass ceramic body of the second aspect just needs to be an amount that does not impair effects of the present invention, specifically, an amount such that, in a cross section as in FIG. 3, that is, a cross section along the thickness directions of the flat alumina particles 12 in the glass ceramic body 10, the total cross sectional area of alumina particles out of the range of the prescribed cross section and ceramic particles other than alumina particles relative to the total area of this cross section is 25% or less, more preferably 20% or less, particularly preferably 15% or less.

The glass ceramic body of the second aspect of the present invention can be manufactured by, for example, a method similar to the method described for the glass ceramic body of the first aspect. However, the manufacturing method is not particularly limited as long as the above structure of the glass ceramic body of the second aspect can be obtained.

The glass ceramic body of the present invention has been described with examples above, but the structure thereof can be changed appropriately and as necessary within a limit that does not go against the gist of the present invention.

[Layered Body]

A layered body of the present invention has a layer constituted of the glass ceramic body of the present invention as at least one layer of a layered structure. Examples of layers other than the glass ceramic body of the present invention constituting the layered body of the present invention include a glass layer, a glass ceramic body layer other than the glass ceramic body of the present invention, a ceramic layer, a metal layer, a resin layer, and the like. The layered structure of the layered body is not particularly limited as long as it has at least one layer constituted of the glass ceramic body of the present invention, and may be chosen appropriately depending on its application.

Among these respective layers, regarding a layer constituted of a material which allows designing with the same firing temperature range, designing as such makes it possible to layer them in a state of green sheet and simultaneously fire them. Further, a layer constituted of a material that cannot be fired simultaneously can be layered by an ordinary method, for example, a method via an adhesive layer, or the like.

[Portable Electronic Device Housing and Portable Electronic Device]

A portable electronic device housing of a first aspect has the glass ceramic body of the first aspect or the glass ceramic body of the second aspect.

A portable electronic device housing of the second aspect has a high reflectivity layer constituted of a glass ceramic body and has reflectivity of 92% or more in a wavelength range of at least 400 to 800 nm. Here, the glass ceramic body in the portable electronic device housing of the second aspect does not exclude use of the glass ceramic body of the first aspect or the glass ceramic body of the second aspect. That is, in the portable electronic device housing of the second aspect, the glass ceramic body of the first aspect or the glass ceramic body of the second aspect can be used as a glass ceramic body as long as predetermined conditions are met.

The portable electronic device housing of the second aspect will be described below as an example. Note that the portable electronic device housing of the first aspect can have the same shape and so on as the portable electronic device housing of the second aspect except that the glass ceramic body of the first aspect or the glass ceramic body of the second aspect is used in at least a part.

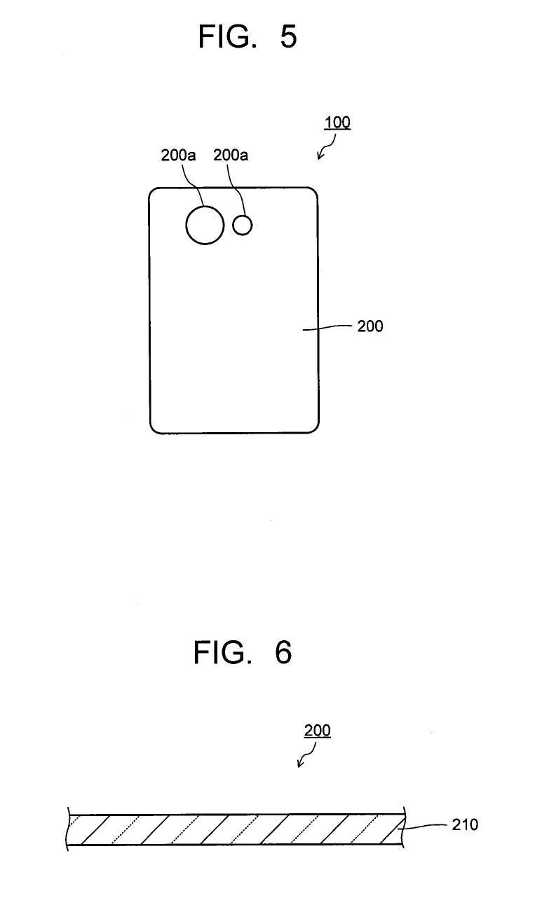

FIG. 5 is a plan view illustrating one embodiment of a portable electronic device. A portable electronic device 100 has, for example, a portable electronic device housing 200 covering substantially the whole rear surface side. Note that in the following, the portable electronic device housing 200 will be simply denoted as a housing 200. In the housing 200, for example, an opening 200a is provided, and an imaging part or a flash part is provided in this part.

FIG. 6 is a cross-sectional view illustrating one embodiment of the housing 200. The housing 200 has at least a high reflectivity layer 210 constituted of a glass ceramic body, and has reflectivity of 92% or more as the entire housing including this high reflectivity layer 210. Such a housing 200 can be easily made with a white housing color because it has the high reflectivity layer 210 constituted of the glass ceramic body, and reflectivity of 92% or more in visible light region in the entire housing since there is small diffuse transmission light. By having reflectivity of 92% or more, for example, transmission of flash light when a flash part is used can be suppressed, and a high-grade appearance can be made. Here, unless otherwise noted in particular, the reflectivity is in visible light region of wavelength of at least 400 to 800 nm.

Note that in view of light shielding property, the housing 200 is preferred to have reflectivity of 92% or more in the entire inner surface, that is, the entire inner surface of a portion constituted of the glass ceramic body, but a corner portion or the like need not necessarily have reflectivity of 92% or more. The area where reflectivity is not 92% or more is preferably 10% or less, more preferably 5% or less, furthermore preferably 3% or less, particularly preferably 1% or less by an area ratio relative to the entire inner surface. Note that the inner surface means a surface that is not exposed to the outside when it is used for a housing. Incidentally, this reflection is due to inner scattering of a glass ceramic material. Thus, the light shielding property can be maintained even when reflectivity is decreased by painting of an entrance surface of light, or the like.

Although the housing color is not necessarily limited as long as it is white, a surface color in a chromaticity coordinate, resulted from converting tristimulus values of XYZ obtained by an illumination system with a C light source of a D/0 method diffusion illumination perpendicular light receiving method defined in JIS Z 8722 into an L*a*b* color system complying with JIS Z 8729, preferably has L* value of 85 or more, a* value of 0±2.0 or less, b* value of 0±2.0 or less, more preferably has L* value of 90 or more, a* value of 0±1.5 or less, b* value of 0±1.5 or less.

The high reflectivity layer 210 has, preferably, reflectivity of 90% or more by a thickness of 300 μm, more preferably 95% or more. By such reflectivity, high reflectivity can be obtained stably in a thickness range including a thickness dispersion of the high reflectivity layer. Further, for example, as will be described later, sufficient reflectivity in its entirety is obtained also when the thickness of the high reflectivity layer 210 is made relatively thin, and a low thermal expansion layer or low contraction layer having relatively low reflectivity is layered on one or both of main surface sides thereof.

The thickness of the high reflectivity layer 210 is preferably 300 μm or more, more preferably 400 μm or more. By having the thickness of the high reflectivity layer 210 of 300 μm or more, as described above, sufficient reflectivity in its entirety is obtained also when the thickness of the high reflectivity layer 210 is made relatively thin, and a low thermal expansion layer or low contraction layer having relatively low reflectivity is layered on one or both of main surface sides thereof. Although the thickness of the high reflectivity layer 210, it is preferably 1000 μm or less, more preferably 800 μm or less in view of thinning and weight reduction of the housing 200.

The high reflectivity layer 210 is a sintered compact in which ceramic particles are dispersed in a glass matrix. The glass matrix is preferably one containing 40 to 65% of SiO₂, 13 to 18% of B₂O₃, 9 to 42% of CaO, 1 to 8% of Al₂O₃, and 0.5 to 6% of at least one of Na₂O and K₂O, which are expressed as mole percentage based on oxides. By having such a composition, there is almost no light absorption in visible light region in the glass matrix, contributing to high reflectivity as the glass ceramic body.

The more intense the light scattering from the glass ceramic body is, the higher the reflectivity of the glass ceramic body is obtained. There are many that can cause light scattering in the glass ceramic body, and in the case of ceramic particles for example, the larger the refractive index difference between the glass matrix and the ceramic particles are, the more intense the light scattering is obtained. Thus, in order to enhance the light scattering, it is preferred to disperse ceramic particles with a high refractive index such as zirconia particles. On the other hand, industrially available zirconia particles are known to easily aggregate and make gaps. Thus they are difficult to be evenly dispersed and sintered in a glass ceramic body, and it is possible that strength of the glass ceramic body is insufficient.

The above glass composition is preferred because, even when a relatively large amount of zirconia particles or the like is dispersed, they can be sintered sufficiently. Note that although those that can cause light scattering are represented by the ceramic particles in the above, in view of high reflectivity, one having a large refractive index difference with the glass matrix is preferred. For example, crystals crystallized from the glass matrix may be used. Further, in view of high reflectivity, gaps including air layers such as enclosed bubbles are also preferred, but when there are many gaps, there are a concern of insufficient strength as glass ceramics and a possibility of generating an internal defect, making it unable to obtain a favorable electric insulating performance. Therefore, when the gaps are utilized, it needs to be designed by sufficiently taking this trade off into consideration.

The components of the glass matrix used for the high reflectivity layer 210 will be described below.

SiO₂ is a glass network former. When SiO₂ is less than 40%, it is difficult to obtain a stable glass, or chemical durability decreases. In the case where it is desired to increase acid resistance, or the like, SiO₂ is preferably 57% or more, more preferably 58% or more, furthermore preferably 59% or more, particularly preferably 60% or more. When SiO₂ exceeds 65%, the glass melting temperature or the glass transition point (Tg) may become too high, and hence it is preferably 64% or less, more preferably 63% or less.

B₂O₃ is a network former of the glass. When B₂O₃ is less than 13%, the glass melting temperature or Tg may become too high, and hence it is preferably 14% or more, more preferably 15% or more. When B₂O₃ exceeds 18%, it is difficult to obtain a stable glass, or chemical durability may decrease, and hence it is preferably 17% or less, more preferably 16% or less.

Al₂O₃ is a component which increases stability, chemical durability or strength of the glass. When Al₂O₃ is less than 1%, the glass becomes unstable, and hence it is preferably 3% or more, more preferably 4% or more, furthermore preferably 5% or more in view of stability of the glass. When Al₂O₃ exceeds 8%, the glass melting temperature or Tg becomes too high, and hence it is preferably 7% or less, more preferably 6% or less.

CaO is a component which stabilizes the glass, lowers the glass melting temperature, and makes it easy for crystals to separate during firing, and can also decrease Tg of the glass. When CaO is less than 9%, the glass melting temperature may become too high, and hence it is preferably 10% or more. In the case where it is desired to make the glass to easily melt, or the like, CaO is preferably 12% or more, more preferably 13% or more, particularly preferably 14% or more. When CaO exceeds 42%, the glass may become unstable, and in view of stability of the glass, it is preferably 23% or less, more preferably 22% or less, furthermore preferably 21% or less, particularly preferably 20% or less, typically 18% or less.

Na₂O and K₂O are components which decrease Tg, and at least one of them is contained. When the total amount (Na₂O+K₂O) is less than 0.5%, the glass melting temperature or Tg may become too high, and hence it is preferably 0.8% or more. When the total amount exceeds 6%, chemical durability, particularly acid resistance may decrease, or electrical properties or the like of the fired body may decreases, and hence it is preferably 5% or less, more preferably 4% or less.

In the glass composition, for example, in view of obtaining relatively high chemical durability, one containing 57 to 65% of SiO₂, 13 to 18% of B₂O₃, 9 to 23% of CaO, 3 to 8% of Al₂O₃, and 0.5 to 6% of at least one of Na₂O and K₂O is more preferred, and one containing 57 to 65% of SiO₂, 13 to 18% of B₂O₃, 9 to 17% of CaO, 4 to 7% of Al₂O₃, and 0.5 to 4% of at least one of Na₂O and K₂O is furthermore preferred.

Further, in the glass composition, for example, in view of obtaining a particularly high strength, one containing 40 to 50% of SiO₂, 13 to 18% of B₂O₃, 25 to 42% of CaO, 1 to 5% of Al₂O₃, and 0.5 to 4% of at least one of Na₂O and K₂O is more preferred.

Although the glass matrix is preferred to be constituted essentially of the above components, it can contain any other components within the range that does not impair the object of the present invention. When other components are contained, the total content thereof is preferably 10% or less. For example, TiO₂ can be contained for the purpose of decreasing viscosity of glass molten liquid, and the content thereof is preferably 3% or less. Further, for the purpose of improving stability of the glass, ZrO₂ can be contained, and the content thereof is preferably 3% or less. Further, for refractive index adjustment, chemical resistance improvement, and adjustment of crystallinity, Nb₂O₅ may be contained. The content thereof is preferably 10% or less. Note that it is preferred not to contain a lead oxide.

The high reflectivity layer 210 preferably contains 40 to 70% of the glass matrix and 30 to 60% of the ceramic particles, which are expressed as volume percentage. When the content of the glass matrix is less than 40%, it is possible that a fine fired body cannot be obtained by firing, and hence it is preferably 45% or more. Further, when the content of the glass matrix exceeds 70%, strength may become insufficient, and hence it is preferably 65% or less, more preferably 60% or less.

The ceramic particles are components which increase strength. The content of the ceramic particles is more preferably 30% or more, particularly preferably 35% or more. When the content of the ceramic particles exceeds 60%, it is possible that a fine fired body cannot be obtained by firing. Or smoothness of a surface may be impaired, and hence it is more preferably 55% or less.

The ceramic particles are typically alumina particles. By containing alumina particles, strength can be increased. Further, when it is desired to increase reflectivity, the refractive index difference with the glass matrix can be sufficiently high, 0.3 or more for example, if high refractive index ceramic particles having a refractive index of more than 2 are used together, which are hence preferred. Further, it is conceivable that the sizes of scattering particles and surface irregularities contribute to the magnitude of scattering power. The scattering power improves more as the sizes of scattering particles are smaller in a Mie scattering region. The diameters of the scattering particles are preferably equal to or more than at least a half-wavelength of incident light. Examples of high refractive index ceramics particles satisfying this include titania particles, zirconia particles, niobium oxide particles, and the like. The titania particles and the zirconia particles have sufficient strength themselves, and hence also are ceramic particles which improves strength of the high reflectivity layer 210.

When the high refractive index ceramic particles are used together, the high refractive index ceramic particles are preferably 20 to 50%, more preferably 25 to 45% in the total amount 100% of the alumina particles and the high refractive index ceramic particles, which are expressed as volume percentage. By such a content ratio, the strength can be high, and the reflectivity can also be high.

Fifty percent particle diameter (D₅₀) of the ceramic particles is preferably 0.1 to 5 μm. When D₅₀ is less than 0.1 μm, for example, it is possible that the ceramic particles cannot be dispersed evenly in the glass matrix, or the ceramic particles easily aggregate and decreases handleability. D₅₀ is more preferably 0.3 μm or more. When D₅₀ exceeds 5 μm, it becomes difficult to obtain a fine fired body, and hence it is more preferably 3 μm or less.

The high reflectivity layer 210 preferably has flat alumina particles because a high strength can be obtained, and particularly the main components of the alumina particles in the high reflectivity layer 210 are preferably flat alumina particles. Further preferably, minor axis directions of the flat alumina particles are basically in the substantially same direction as the thickness direction of the high reflectivity layer 210.

Specifically, when a cross section along its thickness direction is observed with SEM, the high reflectivity layer 210 more preferably includes a large number of flat alumina particles having a length of 1 to 5 μm in the horizontal direction (direction perpendicular to the thickness direction of the high reflectivity layer 210) of the flat alumina particles in this cross section, a length of 0.2 to 1 μm in the thickness direction (thickness direction of the high reflectivity layer 210), and an aspect ratio (horizontal direction length/thickness direction length) of 3 to 18. Particularly, the area ratio occupied by the flat alumina particles having such lengths and aspect ratio in a unit area of 100 μm² of this cross section is preferably 10 to 45%. As the high reflectivity layer 210 used for the housing 200, strength more sufficient than conventional ones can be obtained by having the aspect ratio of about 3 to 10, but for further strength improvement, preferably, ones having an aspect ratio of 3 to 18 are used.

Here, the high reflectivity layer 210 is formed by, for example, forming a green sheet by the doctor blade method and thereafter firing it. At this time, when alumina particles having a rather large aspect ratio are used, after the green sheet is formed by the doctor blade method, minor axis directions of the alumina particles are aligned in a substantially same direction as a thickness direction of the green sheet, and major axis directions of the alumina particles are aligned in the substantially same direction as a formation direction of the green sheet. Therefore, by firing such green sheet, a layer is obtained in which the minor axis directions of the flat alumina particles are in the substantially same direction as the thickness direction of the high reflectivity layer 210. In view of this, as the above-described cross section for observation, when a formation direction thereof during manufacturing is known, a cross section along a formation direction, that is, a cross section along the thickness direction and also a cross section along the formation direction is preferred. Such a cross section is preferred because lengths close to original lengths in the major axis direction can be observed since the lengths in the major axis direction of the flat alumina particles are observed longer.

When the flat alumina particles are used, as the glass matrix, one having the above-described glass composition with which a particularly high strength can be obtained, that is, one containing 40 to 50% of SiO₂, 13 to 18% of B₂O₃, 25 to 42% of CaO, 1 to 5% of Al₂O₃, and 0.5 to 4% of at least one of Na₂O and K₂O, which are expressed as mole percentage based on oxides, is preferred. With such composition, three-point bending strength of 300 MPa or more, furthermore 400 MPa or more can be obtained only with the high reflectivity layer 210, that is, a low thermal expansion layer or a low contraction layer, which will be described later, is not used in combination.

Note that as the high reflectivity layer 210, regardless of whether to use flat alumina particles, one which makes a firing shrinkage ratio be 10 to 20% is preferred, one which makes it be 11 to 17% is more preferred, one which makes a thermal expansion coefficient be 55×10⁻⁷/° C. to 70×10⁻⁷/° C. is preferred, and one which makes it be 60×10⁻⁷/° C. to 70×10⁻⁷/° C. is more preferred. Note that the shrinkage need not be anisotropic shrinkage like the low contraction layer.

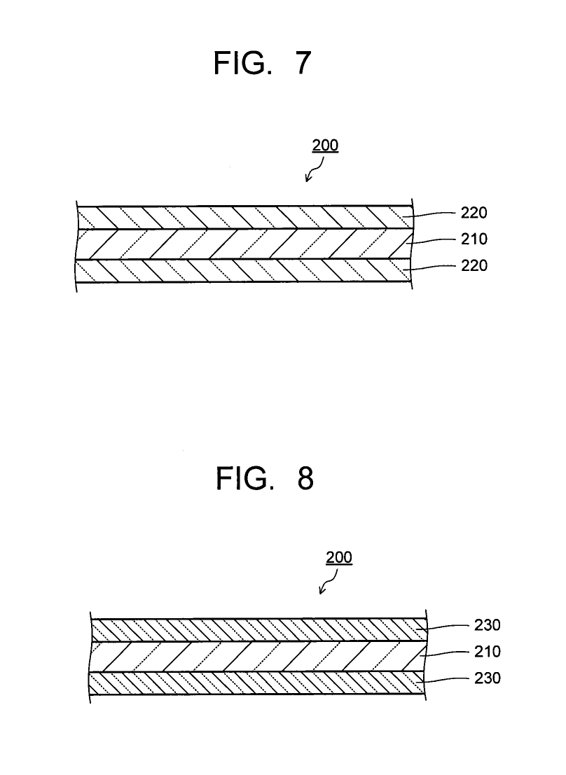

FIG. 7 is a cross-sectional view illustrating a modification example of the housing 200. As illustrated in FIG. 6, the housing 200 may be one constituted only of the high reflectivity layer 210, but when sufficient strength cannot be obtained with only the high reflectivity layer 210, as illustrated in FIG. 7 for example, a pair of low thermal expansion layers 220 constituted of a glass ceramic having a smaller thermal expansion coefficient than the high reflectivity layer 210 is preferably provided on both the main surface sides of the high reflectivity layer 210. By providing the pair of low thermal expansion layers 220 on both the main surface sides of the high reflectivity layer 210, strength of the housing 200 can be improved by a residual stress difference after firing generated by a thermal expansion difference. For example, by providing the pair of low thermal expansion layers 220 on both the main surfaces of the high reflectivity layer 210, the three-point bending strength of the housing 200 can be 300 MPa or more, more preferably 310 MPa or more.

The thermal expansion coefficient of a low thermal expansion layer 220 is not necessarily limited as long as it is lower than the thermal expansion coefficient of the high reflectivity layer 210, but in view of effectively improving the strength of the housing 200, the thermal expansion coefficient difference (thermal expansion coefficient of high reflectivity layer 210−thermal expansion coefficient of low thermal expansion layer 220) is preferably 5×10⁻⁷/° C. or more, more preferably 10×10⁻⁷/° C. or more. In view of suppressing warping of the substrate, the thermal expansion coefficient difference is preferably 50×10⁻⁷/° C. or less, more preferably 40×10⁻⁷/° C. or less.

The thickness of the low thermal expansion layer 220 is not necessarily limited as long as the strength of the housing 200 can be improved, but in view of effectively improving the strength of the housing 200, it is preferably 0.1 time or more of the thickness of the high reflectivity layer 210, more preferably 0.2 time or more. Further, in view of thinning and weight reduction of the housing 200, it is preferably 1 time or less of the thickness of the high reflectivity layer 210, more preferably 0.5 time or less. Note that when the low thermal expansion layers 220 are provided, the thickness of the entire housing 200 is preferably 0.5 to 1.3 mm, more preferably 0.7 to 1.1 mm.

The low thermal expansion layer 220 is a sintered compact in which ceramic particles are dispersed in a glass matrix. Preferably, the glass matrix contains 62 to 84% of SiO₂, 10 to 25% of B₂O₃, 0 to 5% of Al₂O₃, and 0 to 5% of at least one of Na₂O and K₂O, which are expressed as mole percentage based on oxides, in which the sum of contents of SiO₂ and Al₂O₃ is 62 to 84%, content of MgO is 0 to 10%, and the sum of contents of CaO, SrO, and BaO is 5% or less when any of them is contained. With this glass composition, since the content of SiO₂ is relatively large, the thermal expansion coefficient can be made small.

Hereinafter, components of the glass matrix used in the low thermal expansion layers 220 will be described.

SiO₂ is a glass network former and is a component which increases chemical durability, particularly acid resistance. When it is less than 62%, acid resistance may become insufficient. When it exceeds 84%, the glass melting temperature may become high or Tg may become too high.

B₂O₃ is a network former of the glass. When B₂O₃ is less than 10%, the glass melting temperature may become high, or the glass may become unstable. Preferably, it is 12% or more. When B₂O₃ exceeds 25%, it may become difficult to obtain a stable glass, or chemical durability may decrease.

Al₂O₃ is a component which increases stability or chemical durability of the glass, and can be contained in the range of 5% or less. When it exceeds 5%, transparency of the glass may decrease.

The sum of the contents of SiO₂ and Al₂O₃ is 62 to 84%. When it is less than 62%, the chemical durability may become insufficient. When it exceeds 84%, the glass melting temperature may become high or Tg may become too high.

Na₂O and K₂O are components which decrease Tg, and can be contained up to a total amount of 5% (Na₂O+K₂O). When the total amount exceeds 5%, chemical durability, particularly the acid resistance may decrease. Further, an electric insulating property of the fired body may decrease. The total content (Na₂O+K₂O) is preferably 0.9% or more.

MgO may be contained up to 10% for lowering Tg or stabilizing the glass. When it exceeds 10%, silver coloring may become easily. Preferably, it is 8% or less.

CaO, SrO, and BaO are all not essential, but they may be contained up to 5% in total for lowering the glass melting temperature or stabilizing the glass. When it exceeds 5% in total, acid resistance may decrease.

As the glass matrix of the low thermal expansion layer, one containing 78 to 84% of SiO₂, 16 to 18% of B₂O₃, 0 to 0.5% of Al₂O₃, 0 to 0.6% of CaO, 0.9 to 4% in total of at least one of Na₂O and K₂O (glass A), or one containing 72 to 78% of SiO₂, 13 to 18% of B₂O₃, 2 to 10% of MgO, 0.9 to 4% of at least one of Na₂O and K₂O (glass B) is more preferred.

Although the glass matrix is preferred to be constituted essentially of the above contents, other components may be contained in the range that does not impair the object of the present invention. When other components are contained, the total content thereof is preferably 10% or less.

The low expansion layer 22 preferably contains 40 to 70% of the glass matrix, 30 to 60% of the ceramic particles, which are expressed as volume percentage. When the content of the glass matrix is less than 40%, it is possible that a fine fired body cannot be obtained when it is fired. It is preferably 45% or more. Further, when the content of the glass matrix is more than 70%, strength may become insufficient, and hence it is preferably 65% or less, more preferably 60% or less.

The ceramic particles are components which increase strength. The content of the ceramic particles is more preferably 30% or more, particularly preferably 35% or more. When the content of the ceramic particles exceeds 60%, it is possible that a fine fired body cannot be obtained by firing. Or smoothness of a surface may be impaired, and hence it is more preferably 55% or less.

The ceramic particles are typically alumina particles. By containing alumina particles, strength can be increased. Fifty percent particle diameter (D₅₀) of the ceramic particles is preferably 0.1 to 5 μm. When D₅₀ is less than 0.1 μm, for example, it is possible that the ceramic particles cannot be dispersed evenly in the glass matrix, or the ceramic particles easily aggregate and lowers handleability. D₅₀ is more preferably 0.3 μm or more. When D₅₀ exceeds 5 μm, it becomes difficult to obtain a fine fired body, and hence it is more preferably 3 μm or less.

FIG. 8 is a cross-sectional view illustrating another modification example of the housing 200. The housing 200 may be provided with a pair of low contraction layers 230 constituted of glass ceramics having a smaller firing shrinkage ratio than the high reflectivity layer 210 on both the main surfaces of the high reflectivity layer 210 as illustrated in FIG. 8 for example, instead of providing the low thermal expansion layers 220 as illustrated in FIG. 7. By providing the pair of low contraction layers 230 on both the main surfaces of the high reflectivity layer 210, strength of the housing 200 can be improved by the residual stress difference. For example, by providing the pair of low contraction layers 230 on both the main surfaces of the high reflectivity layer 210, the three-point bending strength of the housing 200 can be 300 MPa or more, more preferably 310 MPa or more.

The firing shrinkage ratio of the low contraction layers 230 is not necessarily limited as long as it is lower than the firing shrinkage ratio of the high reflectivity layer 210, but in view of effectively improving the strength of the housing 200, the firing shrinkage ratio difference (firing shrinkage ratio of high reflectivity layer 210−firing shrinkage ratio of low contraction layer 230) is preferably 5% or more, more preferably 10% or more. In view of suppressing warping of the substrate, the firing shrinkage ratio difference is preferably 20% or less, more preferably 15% or less.

The thickness of the low contraction layers 230 is not necessarily limited as long as the strength of the housing 200 can be improved, but in view of effectively improving the strength of the housing 200, it is preferably 0.1 time or more of the thickness of the high reflectivity layer 210, more preferably 0.2 time or more. By making it 0.1 time or more of the thickness of the high reflectivity layer 210, strength of the housing 200 can be improved effectively. Further, in view of thinning and weight reduction of the housing 200, it is preferably 1 time or less of the thickness of the high reflectivity layer 210, more preferably 0.5 times or less. Note that when the low contraction layers 230 are provided, the thickness of the entire housing 200 is preferably 0.5 to 1.3 mm, more preferably 0.7 to 1.1 mm.

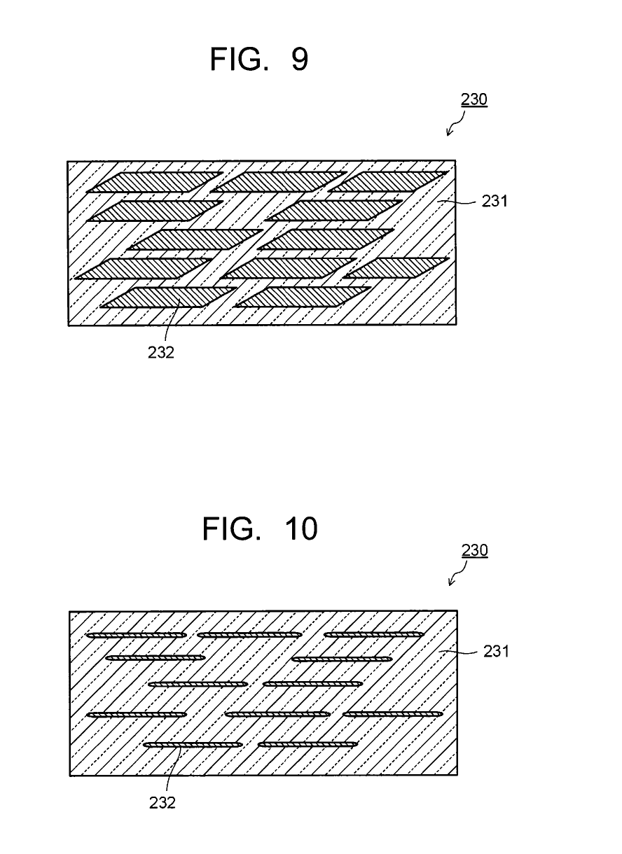

FIG. 9 is a schematic perspective view illustrating an example of a low contraction layer 230, and FIG. 10 is a schematic cross-sectional view along the thickness direction of the low contraction layer 230. The low contraction layer 230 is a sintered compact in which flat ceramic particles 232 are dispersed in a glass matrix 231, and one in which thickness directions (minor axis directions) of the flat ceramic particles 232 are dispersed in a substantially same direction as each other is preferred.

Particularly, the thickness directions of the flat ceramic particles 232 are preferably in a substantially same direction as the thickness direction of the low contraction layer 230, in other words, flat surfaces thereof are preferably substantially parallel with a main surface of the low contraction layer 230. Note that the thickness directions of the flat ceramic particles 232 are, for example, up and down directions in the view in the case illustrated in FIG. 10, and the flat directions are directions perpendicular to the thickness directions (left and right direction in FIG. 10).

By dispersing the flat ceramic particles 232 so that their thickness directions are in the substantially same direction, regarding the flat direction, the flat ceramic particles 232 are butted against each other and thereby movement is suppressed, suppressing firing contraction. Further, by adjusting sizes of the flat ceramic particles 232 in the flat direction, the firing shrinkage in this direction can be controlled. Moreover, it is conceivable that the flat ceramic particles have an increased specific surface area and high reflectivity as compared to non-flat ones.

In cross-sectional observation as illustrated in FIG. 10, the flat ceramic particles 232 have a length of 0.5 to 20 μm in the flat direction (left and right direction in the view) and a length of 0.02 to 0.25 μm in a thickness direction (up and down direction in the view), and an aspect ratio (length in flat direction/length in thickness direction) of 25 to 80 in this cross section. That is, the flat ceramic particle is a general term for ones having a larger aspect ratio than the flat alumina particle described previously. When alumina is used for the flat ceramic particles, it will be described as “high-aspect-ratio alumina particles” or the like so as to distinguish it from the flat alumina particles described previously. It is preferred that the flat ceramic particles are dispersed and contained so that the area ratio occupied by them in a unit area of the cross section is 30 to 48%. Note that the area ratio is preferably 35% or more.

Note that the area ratio is calculated by measuring using SEM and image analysis apparatus areas of the flat ceramic particles 232 whose lengths in this cross section satisfy the above condition in an arbitrary range of 100 μm² in this cross section, and summing them up. Ones satisfying the above condition are all summed up even those having a different chemical composition, like alumina and mica.

The low contraction layer 230 is formed by, for example, forming a green sheet by the doctor blade method and firing it. At this time, when the flat ceramic particles 232 are used, during formation of the green sheet by the doctor blade method, the thickness directions (minor axis directions) of the flat ceramic particles 232 are aligned in a substantially same direction as a thickness direction of the green sheet, and major axis directions of the flat ceramic particles 232 are aligned in a substantially same direction as the forming direction of the green sheet. Therefore, by firing such green sheet, a layer is obtained in which at least the thickness directions of the flat ceramic particles 232 are in a substantially same direction as the thickness direction of the low contraction layer 230. In view of this, as the above-described cross section for observation, when a formation direction thereof during manufacturing is known, a cross section along a formation direction, that is, a cross section along the thickness direction and also a cross section along the formation direction is preferred. Such a cross section is preferred because lengths close to original lengths in the flat direction can be observed since the lengths in the flat direction of the flat ceramic particles 232 are observed longer.

By making the area ratio occupied by the flat ceramic particles 232 in the unit area of the cross section be 30% or more, the firing contraction can be suppressed, and high reflectivity can be obtained. On the other hand, by making the area ratio be 48% or less, decrease in sinterability due to decrease in ratio of the glass matrix 231 is suppressed, generation of pores in the surface can be suppressed and also the strength is sufficient.

Note that as a flat ceramic powder as a raw material powder (flat ceramic particles 232), ones having a mean maximum length, which is an average of maximum lengths in the flat direction, of 0.5 to 20 μm and a mean thickness, which is an average value of lengths in the thickness direction, of 0.02 to 0.25 μm are preferred. Further, a mean aspect ratio (mean maximum length/mean thickness) of 25 to 80 is preferred, which is a ratio of a mean maximum length relative to this mean thickness. Note that ones having different mean aspect ratios can be mixed and used as the flat ceramic powder as a raw material powder. In this case, a total value of values obtained by multiplying mean aspect ratios of respective flat ceramic powders and existence ratios thereof is taken as an apparent mean aspect ratio.

Further, in the content ratio of the flat ceramic particles 232 by which the above area ratio can be obtained, the flat ceramic particles 232 are preferably 30 to 60%, more preferably 35 to 55% in the total amount 100% of the glass matrix 231 and the flat ceramic particles 232, which are expressed as volume percentage. By having the content ratio of 30 to 60% of the flat ceramic particles 232, the above area ratio can be obtained easily.

As the flat ceramic particles 232, for example, ones constituted of a ceramic such as alumina, silica, mica, or boron nitride, are used. Among them, ones constituted of alumina or mica are used preferably.

The low contraction layers 230 can contain irregular particles in addition to the flat ceramic particles 232. Examples of the irregular particles include ones constituted of alumina, silica, zirconia, titania, magnesia, mullite, aluminum nitride, silicon nitride, silicon carbide, forsterite, and cordierite, or the like. The irregular particles are preferably up to 20% of the entire low contraction layer 230, which are expressed as volume percentage.

As the glass matrix 231 of the low contraction layers 230, an SiO₂—B₂O₃ based glass is preferred, an SiO₂—B₂O₃-MO based (M: alkaline earth metal) glass is more preferred, and an SiO₂—B₂O₃—Al₂O₃-MO based (M: alkaline earth metal) glass is particularly preferred.

The glass matrix 231 preferably contains SiO₂, B₂O₃ which become a network former of the glass, and Al₂O₃ which increases stability, chemical durability, and strength of the glass. The total content of SiO₂, B₂O₃, and Al₂O₃ is preferably 57% or more, more preferably 62% or more, furthermore preferably 67% or more which are expressed as mole percentage based on oxides.

An alkaline earth metal oxide may be added for increasing the stability of the glass, lowering the glass melting temperature and Tg, and improving sinterability. As the alkaline earth metal oxide, particularly CaO is preferred because it can make sinterability favorable when the flat ceramic particles 232 are contained. In view of stability, glass melting temperature, Tg, sinterability, and so on of the glass, the content of the alkaline earth metal oxide is preferably 0 to 40%. By containing the alkaline earth metal oxide, excessive increase in glass melting temperature can be suppressed. On the other hand, by having the content of the alkaline earth metal oxide of 40% or less, excessive increase in refractive index of the glass matrix can be suppressed, and a refractive index difference with the flat ceramic particles 232 can be made large to have high reflectivity. The content of the alkaline earth metal oxide is preferably 15 to 40%, more preferably 20 to 40%.

Alkaline metal oxides such as K₂O, Na₂O which lower Tg can be added in the range of 0 to 10% by total amount. These alkaline metal oxides have a significantly low degree of increasing the refractive index compared to the alkaline earth metal oxide, and hence are preferred to be contained in view of manufacturing a glass having a low refractive index. However, when the total content of K₂O and Na₂O exceeds 10%, chemical durability, particularly acid resistance may decrease, and electronic insulating performance may also decrease. The total content of K₂O and Na₂O is preferably 1 to 8%, more preferably 1 to 6%.

ZnO, TiO₂, SnO can be added for the purpose of lowering the softening point similarly to the alkaline earth metal oxide. However, these components have a large degree of increasing the refractive index as compared to other additive components, and hence are preferred to be 20% or less by total amount.

Note that the glass is not necessarily limited to ones constituted of the above components, and other components can be contained in a range satisfying characteristics such as a refractive index difference with the ceramic particles. When other components are contained, the total content is preferably 10% or less, more preferably 5% or less.

When alumina is used for the flat ceramic particles 232, for example, the high-aspect-ratio alumina particles can be manufactured by a method manufacturing boehmite particles by hydrothermal synthesis of aluminum hydroxide, and thermally treating the boehmite particles. By such method, by a heat treatment of boehmite particles, particularly adjustment of heat treatment temperature, a crystal structure can be adjusted. As the high-aspect-ratio alumina particles, for example, ones made by Kinsei Matec (product name: Serath) or the like can also be used preferably.

The high-aspect-ratio alumina particles can be manufactured by, for example, firing the flat boehmite particles obtained by the above method at a temperature of 450 to 1500° C. by an electronic furnace or the like. At this time, γ-alumina type crystal structure can be mainly obtained at 450 to 900° C., δ-alumina type crystal structure can be mainly obtained at 900 to 1100° C., θ-alumina type crystal structure can be mainly obtained at 1100 to 1200° C., α-alumina type crystal structure can be mainly obtained at 1200 to 1500° C.

The alumina particles obtained by firing the boehmite particles retain a shape of boehmite particles before firing, and this does not depend on the type of alumina. Therefore, by using flat ones as the boehmite particles, the high-aspect-ratio alumina particles can be obtained.

The firing time is preferably 1 to 4 hours, further preferably 1.5 to 3.5 hours. When it is less than one hour, the firing is insufficient and it is difficult to obtain the alumina particles. Further, aluminization mostly completes within four hours, and thus firing over four hours is not economical.

As the method for manufacturing the high-aspect-ratio alumina particles, the above method is exemplified as a preferred one, but it is not necessarily limited to this method. A publicly known manufacturing method can be employed appropriately as long as it can allow obtaining a predetermined crystal structure and shape.

In the housing 200, a glassy layer is preferably provided on an uppermost surface of at least one of main surface sides. By providing the glassy layer on the uppermost surface of the housing 200, the surface can be made smooth, and for example, adhesion of stain can be suppressed, or removal of a stain by wiping or the like which has adhered once becomes easy. The glassy layer may be provided on only one of main surface sides where a stain adhere easily, but in view of suppressing warping during firing, or the like, providing on both of main surface sides is preferred.

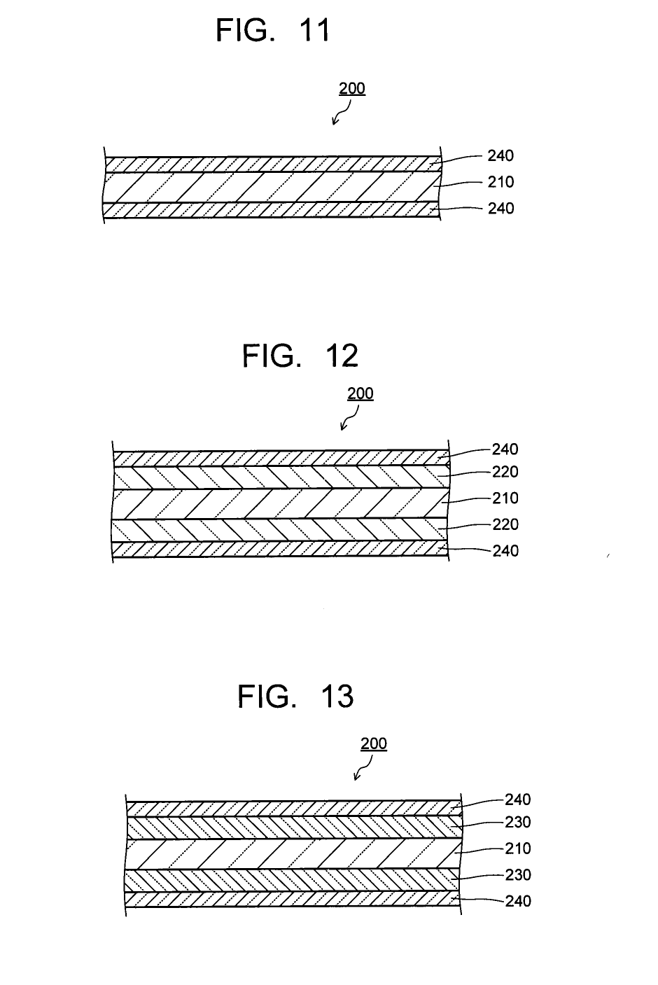

FIGS. 11 to 13 are cross-sectional views of the housing 200 having glassy layers. For example, glassy layers 240 may be provided on both of main surfaces of the high reflectivity layer 210 as illustrated in FIG. 11, may be provided on both of main surfaces of the low thermal expansion layers 220 as illustrated in FIG. 12, or may be provided on both of main surfaces of the low contraction layers 230 as illustrated in FIG. 13.

The thickness of the glassy layers 240 is preferably 5 to 20 μm. When it is 5 μm or more, sufficient flatness can be easily made. Further, when it is 20 μm or less, ones excellent in productivity can be made.

The glassy layers 240 are not particularly limited as long as they are transparent or have a white color, and may be ones constituted only of a glass or ones in which ceramic particles are dispersed in a glass. The glass composition is not particularly limited, but for example, a glass composition illustrated below is preferred.

Specifically, as the glass composition, for example, a composition is preferred which contains 40 to 65% of SiO₂, 13 to 18% of B₂O₃, 9 to 42% of CaO, 1 to 8% of Al₂O₃, 0.5 to 6% of at least one of Na₂O and K₂O, which are expressed as mole percentage based on oxides. By such ones, since it is the same composition as the glass composition of the high reflectivity layer 210, for example, during firing of the high reflectivity layer 210, the matrix components in the high reflectivity layer 210 can be made to exude to form them simultaneously by performing firing at a higher temperature than usual. That is, an operation of newly performing application of a paste or the like can be omitted for forming the glassy layers 240.

Further, as the glass composition, it contains 62 to 84% of SiO₂, 10 to 25% of B₂O₃, 0 to 5% of Al₂O₃, and 0 to 5% in total of at least one or more of Na₂O and K₂O, which are expressed as mole percentage based on oxides, in which the sum of contents of SiO₂ and Al₂O₃ is 62 to 84%, content of MgO is 0 to 10%, and the sum of contents of CaO, SrO, and BaO is 5% or less when at least one or more of them is contained. Also regarding such ones, since it is the same composition as the glass composition of the low thermal expansion layers 220, for example, during firing of the low thermal expansion layers 220, the low thermal expansion layers 220 can be made to exude to form them simultaneously by performing firing at a higher temperature than usual.

Next, a method for manufacturing the housing 200 will be described. The housing 200, that is, the high reflectivity layer 210, the low thermal expansion layers 220, and the low contraction layers 230 can be manufactured by using a green sheet glass ceramic composition constituted of a green sheet glass particles and a green sheet ceramic particles to manufacture respective green sheets, and layering and firing the green sheets.

The green sheet glass particles is normally manufactured by pulverizing a glass obtained by a melting method. This glass corresponds to the glass composition of the glass matrix in each layer. The method of pulverizing may either be dry grinding or wet grinding. In the case of the wet grinding, water is used preferably as a solvent. Further, a pulverizer such as a roll mill, a ball mill, a jet mill, or the like can be used appropriately for pulverizing. After pulverized, the glass are dried and classified as necessary.

A predetermined green sheet ceramic particles is added to this green sheet glass particles to make a glass ceramic composition. Moreover, this green sheet glass ceramic composition and a resin such as polyvinyl butyral or acrylic resin are mixed, with a plasticizer such as dibutyl phthalate, dioctyl phthalate, or butyl benzyl phthalate, or the like being added as necessary.

Moreover, a solvent such as toluene, xylene, butanol is added to make a slurry, and this slurry is formed in a sheet shape by the doctor blade method or the like on a film of a polyethylene terephthalate or the like. When the flat alumina particles (for the high reflectivity layer 210), the flat ceramic particles (for the low contraction layers 230), or the like is used as the green sheet ceramic particles, the minor axis directions of the particles are aligned in a substantially same direction as each other and the minor axis directions of the particles are aligned in a substantially same direction as the thickness direction of the green sheet during formation by this doctor blade method. Finally, this sheet shaped one is dried, and the solvent is removed therefrom, thereby making the green sheet. By punching this green sheet, for example, there is obtained a green sheet having a substantially same shape as the housing 200 and having hole portions to be the openings 200a.

On both of main surfaces of the green sheet to be the high reflectivity layer 210 obtained in this method, green sheets to be the low thermal expansion layer 220 or green sheets to be the low contraction layer 230 are layered as necessary. Further, when the glassy layer 240 is formed, a glass paste for forming the glassy layer 240 on one or both of main surfaces of this layered body is applied as necessary. The glass paste is manufactured by manufacturing glass particles for a glassy layer having a predetermined glass composition similarly to the above manufacturing of the green sheet glass particles, and making a paste from this.

Thereafter, degreasing for decomposing and removing the binder or the like is performed, and subsequently firing is performed to sinter the glass ceramic composition.

The degreasing can be performed by, for example, retaining for 1 to 10 hours at a temperature of 500 to 600° C. When the degreasing temperature is lower than 500° C. or the degreasing time is less than one hour, it is possible that the binder or the like cannot be decomposed and removed sufficiently. When the degreasing temperature is about 600° C. and the degreasing time is about 10 hours, the binder and so on can be removed sufficiently, but exceeding this time length may conversely decrease productivity, and the like.

The firing is performed by, for example, retaining for 20 to 60 minutes at a temperature of 850 to 900° C. When the firing temperature is lower than 850° C. or the firing time is less than 20 minutes, it is possible that a fine sintered compact cannot be obtained. When the firing temperature is about 900° C. and the firing time is about 60 minutes, a sufficiently fine one can be obtained. Note that when the glassy layer 24 is formed by making the matrix components in the green sheet exude simultaneously as the firing, retaining at 20 to 120 minutes at a temperature of 850 to 1000° C. is preferred. When a glass having a low softening point is used, the firing temperature may be low.

Next, another embodiment of a portable electronic device 100 will be described.

An antenna wiring may be provided in the housing 200. Providing the antenna wiring in the housing 200 is effective for size reduction and thinning of the portable electronic device 100. As a material used for the antenna wiring, one that can be fired simultaneously as the glass ceramic body constituting the portable electronic device housing 200 is preferred, and specifically, a silver paste which can be fired by 800 to 900° C. is suitable. However, when it is formed by printing or the like after firing the portable electronic device housing 200, it is not necessarily limited to the silver paste.

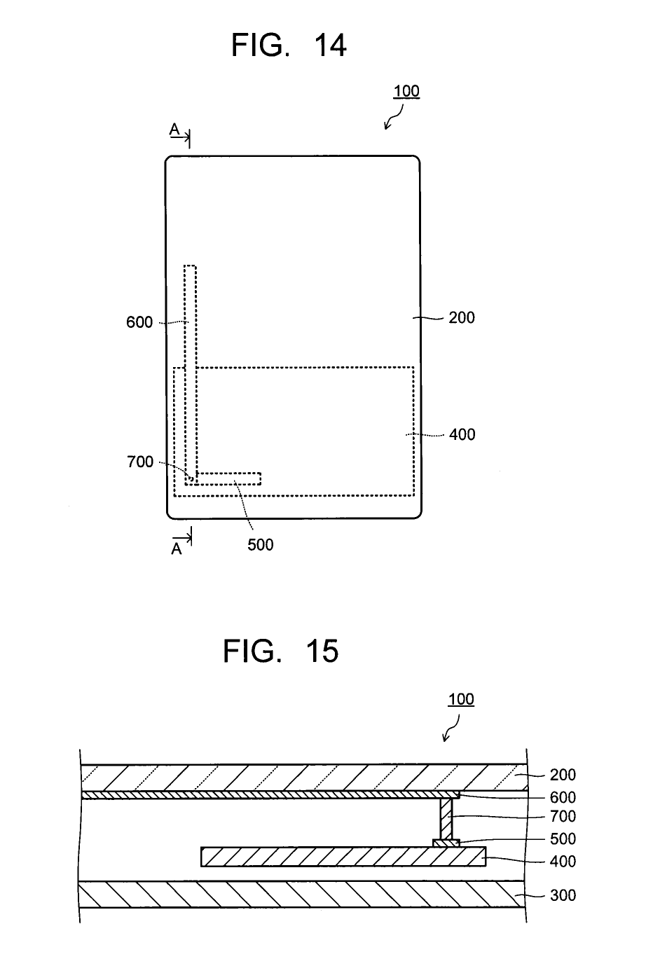

FIG. 14 is a plan view illustrating one embodiment of the portable electronic device 100 in which the housing 200 is provided with the antenna wiring. Further, FIG. 15 is an A-A arrow cross sectional view of the portable electronic device 100 illustrated in FIG. 14.

The portable electronic device 100 has, for example, the housing 200 and a display 300 disposed on a front surface side of this housing 200. A circuit board 400 is disposed between the housing 200 and the display 300. On the surface of the housing 200 side of the circuit board 400, a board side conductor pattern 500 is disposed. Further, on an inner surface of the housing 200, that is, on a surface on the circuit board 400 side, a housing side conductor pattern 600 is disposed as the antenna wiring. The housing side conductor pattern 600 is disposed to extend, for example, in parallel with a long side of the housing 200. The board side conductor pattern 500 and the housing side conductor pattern 600 are disposed so that they partially overlap, and an electric connecting means 700 such as a spring pin is disposed in this overlap portion, electrically connecting the board side conductor pattern 500 and the housing side conductor pattern 600.

The housing side conductor pattern 600 is not necessarily limited on the inner surface of the housing 200, and may be disposed inside the housing 200, which is not illustrated. As a method to disposed the housing side conductor pattern 600 inside the housing 200, for example, when the housing 200 is manufactured by layering plural green sheets, after a non-fired housing side conductor pattern 600 is formed by applying a silver paste or the like on a surface of one green sheet, on a surface on which the non-fired housing side conductor pattern 600 is formed in this green sheet, another green sheet may be layered. Electrical connection of the housing side conductor pattern 600 disposed inside the housing 200 and the circuit board 400 can be made through vias.

Further, the housing side conductor pattern 600 is not limited to disposing only on the inner surface of the housing 200 or only inside the housing 200, and the antenna wiring may be disposed three-dimensionally by disposing the pattern on both the inner surface and the inside of the housing 200. Electrical connection of the housing side conductor pattern 600 on the inner surface and the housing side conductor pattern 600 inside can be made through vias.

For adjusting antenna efficiency, adjusting permittivity of the housing 200 is effective. Generally, the higher the permittivity of a part where an antenna is formed, the more the antenna can be made small. In order to increase the permittivity of the housing 200, increasing permittivity of the glass particles is effective. Further for convenience, a ceramic filler having high permittivity is mixed. A high-refractive-index oxide such as ZrO₂, TiO₂, and Nb₂O₅, or a composite oxide of perovskite-type structure such as BaTiO₂ can be exemplified as ceramic filter materials having high permittivity. In order to decrease permittivity conversely, a ceramic filler having low permittivity is chosen. Further, the permittivity can be adjusted by layering green sheets having different permittivity.

In consideration of design of the housing 200, it is also possible to color the housing 200 to other than white. Coloring of the housing 200 is performed by, for example, a colored glass particles. For coloring of the glass particles, as a coloring component, an element which causes absorption when added to a glass composition, such as Co, Mn, Fe, Ni, Cu, Cr, V, Zn, Bi, Er, Tm, Nd, Sm, Sn, Ce, Pr, Eu, Ag, or Au, may be added as oxide, fluoride, inorganic acid salt such as carbonate, nitrate, hydrochloride, or sulfate, organic acid salt, ammonium salt, or any other salt. Further, as the glass ceramic, by adding and mixing a pigment powder and sintering it is higher in degree of flexibility in color tone adjustment. As a typical inorganic pigment, a composite oxide type pigment constituted of elements selected from Fe, Cr, Co, Cu, Mn, Ni, Ti, Sb, Zr, Al, Si, P, or the like can be exemplified.

Thus, the portable electronic device of the present invention has been described, and the portable electronic device of the present invention includes all portable electronic devices including a portable wireless communication device, and includes, for example, portable phone, electronic notebook, portable information assistant (PDA), smartphone, digital camera, and equivalent products thereof. Further, the housing 200 is not limited to one having only one of the low thermal expansion layer 220 and the low contraction layer 230, and may be one having both of them. Moreover, the number of layers may be constituted of three or more layers.

### EXAMPLES

Hereinafter, a specific description will be given with reference to examples.

### Example: Example 1 to 18, Comparative Example: Examples 19 to 23

### Manufacturing Glass Particles

Respective glass materials were compounded and mixed to have a raw material mixture for making a glass of a ratio (mole percentage based on oxides) presented in Table 2, this raw material mixture was put in a platinum crucible, melted for 60 minutes at 1200 to 1500° C., and thereafter the molten product was poured out and cooled. Then, the cooled product was pulverized for 10 to 60 hours by an alumina ball mill with water being a solvent and classified, thereby obtaining glass particles G1 to G4 of respective compositions. Table 2 also presents 50% particle diameters (D₅₀) of the glass particles G1 to G4. Note that in the compositions of glass particles G1 to G4 in Table 3, there are presented mole percentages based on oxides of the respective components given that a composition excluding Al₂O₃ is 100%.

TABLE 2

| Glass composition abbreviation | | G1 | G2 | G3 | G4 |
|---|---|---|---|---|---|
| Glass | SiO₂ | 46.6 | 60.4 | 47.9 | 45.5 |
| composition | B₂O₃ | 15.1 | 15.6 | 15.6 | 16.8 |
| (mol %) | CaO | 32.6 | 15.0 | 27.5 | 28.7 |
| | SiO₂ + B₂O₃ + | 94.3 | 91.0 | 91.0 | 91.0 |
| | CaO | | | | |
| | Al₂O₃ | 2.8 | 6.0 | 6.0 | 0.1 |
| | SrO | 0.0 | 0.0 | 0.0 | 6.0 |
| | Na₂O | 2.9 | 2.0 | 2.0 | 1.0 |
| | K₂O | 0.0 | 1.0 | 1.0 | 1.9 |

| | | | | |
|---|---|---|---|---|
| D₅₀ (μm) | 1.4 | 1.6 | 1.6 | 1.3 |

TABLE 3

| Glass composition abbreviation | | G1 | G2 | G3 | G4 |
|---|---|---|---|---|---|
| Glass | SiO₂ | 47.9 | 64.3 | 51.0 | 45.5 |
| composition | B₂O₃ | 15.5 | 16.6 | 16.6 | 16.8 |
| (mol %) | CaO | 33.5 | 16.0 | 29.3 | 28.7 |
| | SiO₂ + B₂O₃ + | 97.0 | 96.8 | 96.8 | 91.1 |
| | CaO | | | | |
| | SrO | 0.0 | 0.0 | 0.0 | 6.0 |
| | Na₂O | 3.0 | 2.1 | 2.1 | 1.0 |
| | K₂O | 0.0 | 1.1 | 1.1 | 1.9 |

(Manufacturing Flat Alumina Particles and Irregular Alumina Particles)

Flat boehmite particles were manufactured by hydrothermal synthesis from aluminum hydroxide, and the flat boehmite particles were fired to obtain flat alumina particles. Similarly, irregular alumina particles were obtained from irregular boehmite particles.

Specifically, first, corresponding to each of flat or irregular boehmite particles for obtaining flat or irregular alumina particles presented in Table 4, aluminum hydroxide, sodium hydroxide or calcium carbonate as a pH adjuster, and water were charged in an autoclave. Here, pH was adjusted to 8 or more, and the compounding ratio of water was 5 times or more of the amount of aluminum hydroxide by mass ratio. Then, they were brought into reaction for 2 to 10 hours at 150 to 200° C. under natural pressure. Thereafter, washing with water and filtering were performed, obtaining respective flat boehmite particles and irregular boehmite particles. Note that adjustment for making the flat alumina particles and the irregular alumina particles of the sizes presented in Table 4 was performed by adjusting sizes during manufacturing of the flat boehmite particles and the irregular boehmite particles.

Thereafter, the obtained respective boehmite particles were fired at 1200 to 1400° C., to thereby obtain flat alumina particles A1 to A3 having a mean thickness of 0.4 μm or more, a mean major axis of 10 μm or less, and a mean aspect ratio in the range of 3 to 18, presented in Table 4, and flat alumina particles A4 and irregular alumina particles A5 whose sizes are not in these ranges. Note that measurement of particle sizes of the alumina particles A1 to A5 refers to one calculated by averaging values resulted from measuring lengths of 100 alumina particles by using SEM.

TABLE 4

| Alumina particle abbreviation | A1 | A2 | A3 | A4 | A5 |
|---|---|---|---|---|---|
| Shape | Flat | Flat | Flat | Flat | Irregular |
| Main thickness (μm) | 0.8 | 0.7 | 0.7 | 0.1 | 2.0 |
| Mean major axis (μm) | 5.0 | 7.0 | 4.0 | 3.0 | 3.0 |
| Mean aspect ratio | 6.3 | 10.0 | 5.7 | 30.0 | 1.5 |

(Manufacturing Glass Ceramic Bodies)

Next, as presented in Table 5 with respect to example 1 to example 12 and in Table 6 with respect to example 13 to example 23, glass particles and flat alumina particles, irregular alumina particles, and irregular zirconia particles as ceramic particles were compounded by a predetermined ratio (vol %) and mixed. Note that as the irregular zirconia particles, a zirconia particles whose 50% particle diameter (D₅₀) is 0.5 μm and a specific surface area is 8.0 m²/g (made by Daiichi Kigenso Kagaku Kogyo, product name: HST-3F) was used.

To this mixed particles (glass ceramic composition) 50 g, an organic solvent (mixture of toluene, xylene, 2-propanol, and 2-butanol by a mass ratio of 4:2:2:1) 15 g, a plasticizer (di-2-ethylhexyl phthalate) 2.5 g, polyvinyl butyral (made by Denka, product name: PVK#3000K) 5 g as a binder, and a dispersant (made by BYK-Chemie, product name: BYK 180) 0.5 g were compounded and mixed, thereby making a slurry. This slurry was applied by the doctor blade method on the PET film and dried, and thereafter cut, thereby manufacturing a green sheet having a thickness of 0.2 mm and being 40 mm square (40 mm vertical×40 mm horizontal).

Next, six such green sheets were overlaid with formation directions of the green sheets being aligned in a same direction, and pressure of 10 MPa was applied at 80° C. to integrate them. Thereafter, components other than the glass ceramic composition such as a binder were decomposed and removed by retaining for five hours at 550° C. in a firing furnace, and thereafter firing was performed by retaining for one hour at a firing temperature presented in Table 5 (example 1 to example 12) or Table 6 (example 13 to example 23). Thus, glass ceramic bodies having a thickness of 500 μm with respect to examples 1 to 23 were obtained.

(Evaluation)

The glass ceramic bodies obtained in above examples 1 to 23 were evaluated as follows. Results are presented in lower sections of Table 5 and Table 6.

### <Crystallinity>

As the glass ceramic bodies obtained in examples 1 to 23, when crystallinity of glass matrix was examined by X-ray diffraction using a CuKα ray as a characteristic X ray with respect to the glass ceramic bodies obtained in example 1 to example 23, a peak which can belong to anorthite (CaAl₂Si₂O₈) appeared in examples 12, 14, 15, 23. In all other examples, no peak of crystallized glass was detected by the X-ray diffraction, and it was confirmed that the glass of the glass matrix is not crystallized. Results of the examples having no crystallization are presented as “-” in Table 5 and Table 6.

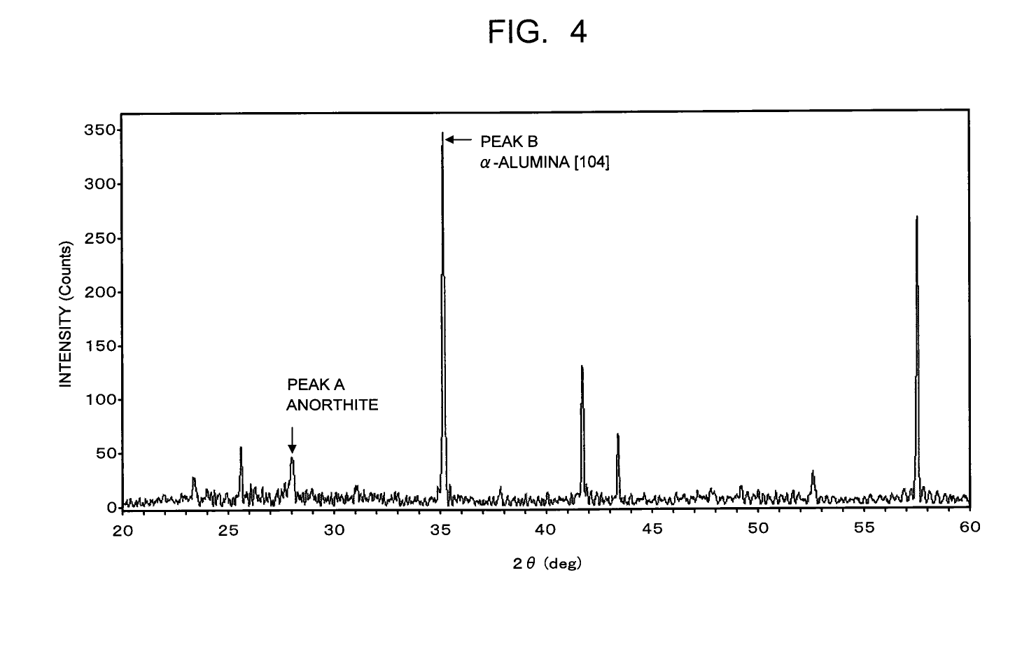

FIG. 4 is a graph of spectrum of X-ray diffraction (XRD) of the glass ceramic body of example 14. The vertical axis of FIG. 4 represents intensity (Counts), and the horizontal axis represents a diffraction angle 2θ (deg.). A peak A (equivalent to I(glass)) corresponding to anorthite (CaAl₂Si₂O₈) appeared at a diffraction angle 2θ=28.0 to 28.1 deg., and a peak B (equivalent to I(Al₂O₃)) corresponding to [104] of alumina (Al₂O₃) appeared at a diffraction angle 2θ=35.1 to 35.3 deg.

The crystallinity was calculated by the above formula (1) by using the measurement results of the X-ray diffraction, that is, the intensity of peak A and the intensity of peak B. In the case of example 14, I(glass)=intensity of peak A was 52 and I(Al₂O₃)=intensity of peak B was 349. That is, from crystallinity (%)=(52/(349+52)×100, 13% was calculated. Calculation was performed similarly, 10% was calculated in example 12, 20% in example 15, and 40% in example 24.

<Cross-Sectional Observation of Flat/Irregular Alumina Particles>

The respective glass ceramic bodies obtained in examples 1 to 18, 19, 22, 23 were cut in the thickness direction and a direction substantially parallel with the formation direction of the doctor blade, and cross sections thereof were mirror polished. Ten different points were observed using a scanning electron microscope (SEM), and cross-sectional maximum diameters and thicknesses of the obtained images were measured individually regarding all alumina particles in a cross section 100 μm² using image analysis software (Winroof, made by Mitani Corporation), to thereby obtain a cross-sectional aspect ratio. Among them, flat alumina particles with the prescribed cross section having a thickness of 0.2 μm or more, a cross-sectional maximum diameter of 8 μm or less and a cross-sectional aspect ratio in the range of 3 to 18 were chosen, and a mean value thereof was obtained. Further, areas of the flat alumina particles with the prescribed cross section in this cross section were measured individually to obtain a total area (μm²) thereof. This was divided by the total cross sectional area 100 μm², and further multiplied by 100, to thereby obtain the area ratio by percentage occupied by the flat alumina particles with the prescribed cross section in the entire area of the cross section. Results are presented in Table 5 and Table 6.

Further, in the respective glass ceramic bodies obtained in examples 20, 21, the flat alumina particles with the prescribed cross section having a thickness of 0.2 μm or more, a cross-sectional maximum diameter of 8 μm or less, and a cross-sectional aspect ratio in the range of 3 to 18 did not exist.

Regarding the respective glass ceramic bodies obtained in examples 20, 21, cross-sectional observation was performed similarly to the above, and regarding alumina particles in all the range in the cross section, mean values of thicknesses, cross-sectional maximum diameters, and cross-sectional aspect ratios were obtained. Further, areas of all alumina particles in this cross section were measured individually to obtain a total area (μm²) thereof. This was divided by the total cross sectional area 100 μm², and further multiplied by 100, to thereby obtain the area ratio by percentage occupied by all the alumina particles in the entire area of the cross section. Results are presented in Table 6.

<Three-Point Bending Strength>

Regarding the respective glass ceramic bodies obtained in examples 1 to 23, a three-point bending strength test complying with JIS C2141 was performed. Specifically, one side of a glass ceramic body was supported by two points, a weight was applied gradually to a middle position of the two points on a side opposing the side, a load when a breakage occurred in the glass ceramic body was measured, and the three-point bending strength (MPa) was calculated based on this. This bending strength was measured at 30 points to obtain a mean value (mean bending strength). Results are presented in Table 5 and Table 6.

<Open Porosity>

Regarding the respective glass ceramic bodies obtained in examples 1 to 23, an open porosity (%) was measured by using an Archimedes method according to JIS R1634. Results are presented in Table 5 and Table 6.

TABLE 5

| | | | Example number | | | | | | | | | | | |
|---|---|---|---|---|---|---|---|---|---|---|---|---|---|---|
| | | | 1 | 2 | 3 | 4 | 5 | 6 | 7 | 8 | 9 | 10 | 11 | 12 |
| Formation | Alumina | Flat/irregular alumina | A1 | A1 | A1 | A2 | A3 | A1 | A1 | A1 | A1 | A1 | A1 | A1 |
| of glass | particles | particle abbreviation | | | | | | | | | | | | |
| ceramic | | Mean thickness (μm) | 0.8 | 0.8 | 0.8 | 0.7 | 0.7 | 0.8 | 0.8 | 0.8 | 0.8 | 0.8 | 0.8 | 0.8 |
| composition | | Mean major axis (μm) | 5.0 | 5.0 | 5.0 | 7.0 | 4.0 | 5.0 | 5.0 | 5.0 | 5.0 | 5.0 | 5.0 | 5.0 |
| | | Mean aspect ratio | 6.3 | 6.3 | 6.3 | 10.0 | 5.7 | 6.3 | 6.3 | 6.3 | 6.3 | 6.3 | 6.3 | 6.3 |
| | | Content (vol %) | 40 | 45 | 50 | 45 | 45 | 30 | 35 | 40 | 45 | 45 | 50 | 45 |
| | Glass | Glass composition | G1 | G1 | G1 | G1 | G1 | G2 | G2 | G2 | G2 | G3 | G3 | G4 |
| | particles | abbreviation | | | | | | | | | | | | |
| | | Content (vol %) | 60 | 55 | 50 | 55 | 55 | 70 | 65 | 60 | 55 | 55 | 50 | 55 |
| | Zirconia particle content (vol %) | | — | — | — | — | — | — | — | — | — | — | — | — |
| Glass | Crystallinity | | — | — | — | — | — | — | — | — | — | — | — | 10% |
| ceramic | Cross- | Mean thickness (μm) | 0.5 | 0.4 | 0.4 | 0.3 | 0.3 | 0.5 | 0.5 | 0.4 | 0.4 | 0.4 | 0.4 | 0.4 |
| body | sectional | Mean cross-sectional | 3.1 | 3.1 | 3.1 | 3.6 | 2.2 | 3.6 | 3.6 | 3.6 | 3.6 | 3.3 | 3.3 | 3.2 |
| | observation | maximum diameter (μm) | | | | | | | | | | | | |
| | (flat | Mean cross-sectional aspect | 7 | 7 | 8 | 12 | 7 | 7 | 8 | 8 | 8 | 8 | 8 | 7 |
| | alumina | ratio | | | | | | | | | | | | |
| | particles) | Area ratio (%) | 28.6 | 36.4 | 38.0 | 34.7 | 34.6 | 23.0 | 26.4 | 32.4 | 39.3 | 40.6 | 42.3 | 42.0 |

| | | | | | | | | | | | | |
|---|---|---|---|---|---|---|---|---|---|---|---|---|
| Three-point bending strength (MPa) | 410 | 490 | 502 | 498 | 470 | 474 | 455 | 474 | 460 | 443 | 458 | 486 |
| Open porosity (%) | 0.0 | 0.0 | 0.0 | 0.0 | 0.0 | 0.0 | 0.0 | 0.0 | 0.0 | 0.0 | 0.0 | 0.0 |

| | | | | | | | | | | | | |
|---|---|---|---|---|---|---|---|---|---|---|---|---|
| Firing temperature (° C.) | 860 | 860 | 860 | 860 | 860 | 860 | 860 | 860 | 860 | 860 | 860 | 860 |

TABLE 6

| | | | Example number | | | | | | | | | | |
|---|---|---|---|---|---|---|---|---|---|---|---|---|---|
| | | | 13 | 14 | 15 | 16 | 17 | 18 | 19 | 20 | 21 | 22 | 23 |
| Formation | Alumina | Flat/irregular alumina | A1 | A1 | A1 | A1 | A1 | A1 | A1 | A4 | A5 | A1 | A1 |
| of glass | particles | particle abbreviation | | | | | | | | | | | |
| ceramic | | Mean thickness (μm) | 0.8 | 0.8 | 0.8 | 0.8 | 0.8 | 0.8 | 0.8 | 0.1 | 2.0 | 0.8 | 0.8 |
| composition | | Mean major axis (μm) | 5.0 | 5.0 | 5.0 | 5.0 | 5.0 | 5.0 | 5.0 | 3.0 | 3.0 | 5.0 | 5.0 |
| | | Mean aspect ratio | 6.3 | 6.3 | 6.3 | 6.3 | 6.3 | 6.3 | 6.3 | 30.0 | 1.5 | 6.3 | 6.3 |
| | | Content (vol %) | 50 | 50 | 50 | 35 | 38 | 40 | 55 | 45 | 45 | 50 | 50 |
| | Glass | Glass composition | G4 | G4 | G4 | G1 | G1 | G1 | G1 | G1 | G1 | G2 | G4 |
| | particles | abbreviation | | | | | | | | | | | |
| | | Content (vol %) | 50 | 50 | 50 | 52 | 52 | 55 | 45 | 55 | 55 | 50 | 50 |
| | Zirconia particle content (vol %) | | — | — | — | 13 | 10 | 5 | — | — | — | — | — |
| Glass | Crystallinity | | — | 13% | 20% | — | — | — | — | — | — | — | 40% |
| ceramic | Cross- | Mean thickness (μm) | 0.4 | 0.4 | 0.4 | 0.4 | 0.4 | 0.4 | 0.4 | 0.1* | 1* | 0.4 | 0.4 |
| body | sectional | Mean cross-sectional | 3.1 | 3.1 | 3.1 | 3.2 | 3.2 | 3.2 | 3.1 | 2.5* | 2* | 3.6 | 3.1 |
| | observation | maximum diameter (μm) | | | | | | | | | | | |
| | (flat | Mean cross-sectional aspect | 7 | 7 | 7 | 7 | 7 | 7 | 8 | 25* | 2* | 9 | 7 |
| | alumina | ratio | | | | | | | | | | | |
| | particles) | Area ratio (%) | 43.1 | 43.1 | 43.1 | 31.1 | 32.0 | 31.6 | 41.2 | 37.7* | 31* | 40.1 | 43.1 |

| | | | | | | | | | | | |
|---|---|---|---|---|---|---|---|---|---|---|---|
| Three-point bending strength (MPa) | 509 | 505 | 404 | 464 | 500 | 460 | 346 | 348 | 280 | 342 | 365 |
| Open porosity (%) | 0.0 | 0.0 | 0.0 | 0.0 | 0.0 | 0.0 | 11 | 0.0 | 0.0 | 8 | 0.0 |

| | | | | | | | | | | | |
|---|---|---|---|---|---|---|---|---|---|---|---|
| Firing temperature (° C.) | 840 | 860 | 880 | 860 | 860 | 860 | 860 | 860 | 860 | 860 | 900 |

*is a value occupied by all alumina particles in the total area of the cross section

As is clear from Table 5 and Table 6, in the glass ceramic body satisfying both the requirements of the first aspect and the requirements of the second aspect of the present invention, which were obtained in example 1 to example 18, the three-point bending strength is more than 400 MPa, which can be said as a high strength. In all the glass ceramic bodies of examples 19 to 23 in which sizes of dispersed alumina particles do not satisfy the requirements of the second aspect, the three-point bending strength is 365 MPa or less and do not have sufficient strength.

### Example: Examples 24 to 27, Comparative Example: Examples 28, 29

### Manufacturing Green Sheets

Respective raw materials were compounded and mixed to have a raw material mixture for having a ratio presented in Table 7, this raw material mixture was put in a platinum crucible, melted for 60 minutes at 1200 to 1500° C., and thereafter the molten product was poured out and cooled. Then, the cooled product was pulverized for 10 to 60 hours by an alumina ball mill with water being a solvent and classified, thereby obtaining glass particles of respective compositions.

Next, a glass particles, an alumina particles (irregular), an alumina particles (high aspect ratio), and a zirconia particles (irregular) were compounded by a predetermined ratio and mixed, thereby obtaining a glass ceramic composition.

An alumina particles (made by Showa Denko, product name: AL-45H) having a 50% particle diameter (D₅₀) of 2 μm and a specific surface area of 4.5 m²/g was used as the alumina particles (irregular), a zirconia particles (made by Daiichi Kigenso Kagaku Kogyo, product name: HSY-3FJ) having 50% particle diameter (D₅₀) of 0.5 μm and a specific surface area of 8.0 m²/g was used as the zirconia particles (irregular).

Further, as the alumina particles (high aspect ratio), one obtained by manufacturing a boehmite particles by hydrothermal synthesis from aluminum hydroxide, and firing this boehmite particles at 800° C. to 1300° C. was used. This alumina particles (high aspect ratio) has a mean maximum length in the flat direction of 1 to 5 μm, a mean thickness in the thickness direction of 0.02 to 0.04 μm, and a mean aspect ratio (mean maximum length/mean thickness) of 30 to 70. Note that adjustment of the mean aspect ratio and so on was performed by adjusting a mean aspect ratio and so on during manufacturing of the boehmite particles.

Note that a flat alumina particles was used for a green sheet “d” described below. This flat alumina particles is one having a length of 1 to 5 μm in the horizontal direction (formation direction) in the following cross section, a length of 0.2 to 1 μm in the thickness direction, and an aspect ratio (horizontal direction length/thickness direction length) of 3 to 10 when the green sheet d is formed and fired and a cross section (cross section along the thickness direction and cross section along the formation direction) is observed by SEM. The area ratio occupied by the alumina particles having such a length and an aspect ratio in the unit area of 100 μm² of the cross section was 30%.

To the glass ceramic composition 50 g obtained in this method, an organic solvent (mixture of toluene, xylene, 2-propanol, and 2-butanol by a mass ratio of 4:2:2:1) 15 g, a plasticizer (di-2-ethylhexyl phthalate) 2.5 g, polyvinyl butyral (made by Denka, product name: PVK#3000K) 5 g as a binder, and a dispersant (made by BYK-Chemie, product name: BYK 180) 0.5 g were compounded and mixed, thereby making a slurry. This slurry was applied by the doctor blade method on the PET film and dried, and thereafter cut, thereby manufacturing a green sheet having a thickness of 130 μm after firing and being 40 mm square (40 mm vertical×40 mm horizontal). Note that four types of green sheets, green sheet “a” (for high reflectivity layer), green sheet “b” (for low contraction layer), green sheet “c” (for low thermal expansion layer), and green sheet “d” (for high reflectivity layer) were made.

(Manufacturing Test Pieces)

Next, the green sheet “a”, the green sheet “b”, the green sheet “c”, and the green sheet “d” were layered so as to have a combination of upper layer to lower layer as presented in Table 8, and pressure of 10 MPa was applied at 80° C. to integrate them. Note that the upper layer and the lower layer were constituted of one green sheet, and a middle layer was constituted of four green sheets. Thereafter, the binder resin was decomposed and removed by retaining for five hours at 550° C. in a firing furnace, and thereafter firing was performed by retaining for one hour at 870° C., thereby obtaining test pieces of example 24 to 29.

Note that firing shrinkage ratios and thermal expansion coefficients of the green sheet “a”, the green sheet “b”, the green sheet “c”, and the green sheet “d” are also presented in Table 7. Here, regarding measurement of the firing shrinkage ratios, a rectangle is cut out in a state of green sheet, and the length between center points of two opposing sides is measured in advance with a vernier caliper. A thickness is measured by vernier caliper in advance. After firing, similarly, the length between center points of two opposing sides is measured with the vernier caliper. The thickness is similarly measured with the vernier caliper. The firing shrinkage ratio defined here is a shrinkage ratio in a flat surface direction of the sheet excluding the thickness direction, and is such that, with respect to each of two sets of lengths between center points of two opposing sides, averaging ratios resulted from dividing a length, which is resulted from subtracting a length after firing from a length before firing, by the length before firing, and they are expressed by %. Further, the measurement of the thermal expansion coefficient is such that a fired body is set to a thermomechanical analyzer (TMA), heated by 10° C./minute, and a length thereof is recorded. It was performed by obtaining a mean thermal expansion coefficient from an initial length and an elongation length in the temperature range of 50° C. to 400° C.

Regarding the test pieces of examples 24 to 29 obtained in this method, measurement of three-point bending strength, reflectivity, and color tone was performed. Results are presented in Table 8.

(Three-Point Bending Strength)

Regarding the test pieces (780 μm thick), the three-point bending strength test (complying with to JIS C2141) was performed. Specifically, one side of a test piece was supported by two points, a weight was applied gradually to a middle position of the two points on a side opposing the side, a load when a breakage occurred in the test piece was measured, and the three-point bending strength (MPa) was calculated based on this. The bending strength was measured at 30 points to obtain a mean value (mean bending strength).

(Reflectivity)

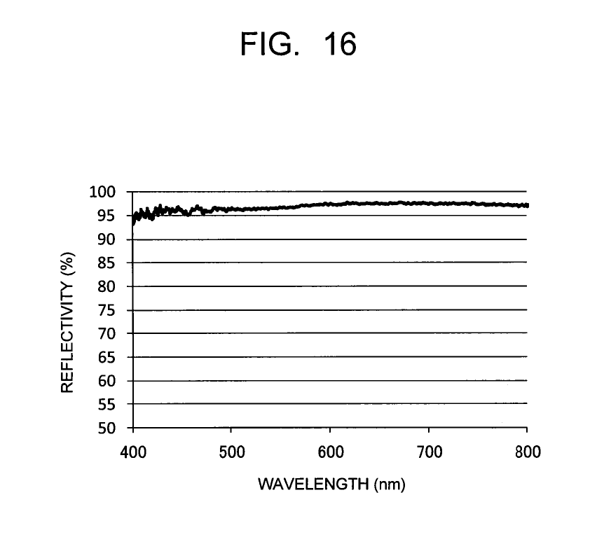

Regarding the test pieces (780 μm thick), reflectivity of a surface was measured. For measuring the reflectivity, a spectroscopy system (made by Ocean Optics, product name: USB2000) using an integration sphere (made by Ocean Optics, product name: ISP-REF) with a light source was used. The light source is a tungsten halogen light source at a color temperature of 3100 K. FIG. 16 is a reflection characteristic of the test piece of example 24. Regarding wavelength dependency of reflectivity, across the entire visible light region of at least 400 to 800 nm, it can be seen that the reflectivity is as high as 92% or more, and it is a substantially flat characteristic. Based on such measurement results, a surface reflectivity of each test piece was represented by a reflectivity (unit: %) at 460 nm. Further, each of L* value, a* value, b* value was calculated.

(Light Shielding Property)

Regarding the test pieces, when an illumination light irradiated by a flash when reflectivity is measured a transmitted light transmitted to a rear side of an irradiation surface was sensory evaluated by visual observation. At this time, an alumina substrate having a thickness of 1 mm and a reflectivity of 92% was used as a standard test piece. In the table, “A” is one having a lower transmitted light than the standard alumina substrate, and “B” denotes one observed as a transmitted light equal to or more than that of the standard test piece.

(Color Tone)

Regarding the test piece, L* value, a* value, b* value were obtained by a chroma meter CR-400 made by Konica Minolta, which are surface colors in a surface color system in a chromaticity coordinate (complying with JIS Z 8729) resulted from converting tristimulus values of XYZ obtained by an illumination system (complying with JIS Z 8722) with a C light source of a diffusion illumination perpendicular light receiving method into an L*a*b* color system.

TABLE 7

| | | Green sheet | | | |
|---|---|---|---|---|---|
| | | | | c | |
| | | a | b | For low | d |
| | | For high | For low | thermal | For high |
| | | reflectivity | contraction | expansion | reflectivity |
| | | layer | layer | layer | layer |
| Glass | SiO₂ | 60 | 48 | 82 | 46 |
| composition | B₂O₃ | 16 | 16 | 16 | 15 |
| [mol %] | Al₂O₃ | 6 | 6 | 0 | 3 |
| | CaO | 15 | 27 | 0 | 33 |
| | Na₂O | 2 | 2 | 0 | 3 |
| | K₂O | 1 | 1 | 2 | 0 |
| Compounding | Glass particles | 50 | 55 | 60 | 52 |
| amount | α-alumina particles (irregular) | 35 | 0 | 40 | 0 |
| [vol %] | α-alumina particles (flat) | 0 | 0 | 0 | 38 |
| | α-alumina particles (high | 0 | 45 | 0 | 0 |
| | aspect ratio) | | | | |
| | Zirconia particles (irregular) | 15 | 0 | 0 | 10 |
| Characteristics | Firing shrinkage ratio [%] | 14 | 4 | 14 | 14 |
| | Thermal expansion coefficient | 64 | 65 | 52 | 65 |
| | [×10⁻⁷/° C.] | | | | |

TABLE 8

| | | | Example | Example | Example | Example | Example | Example |
|---|---|---|---|---|---|---|---|---|
| | | | 24 | 25 | 26 | 27 | 28 | 29 |
| Structure | Upper layer | | Green | Green | Green | Green | Green | Green |
| | (130 μm thick) | | sheet a | sheet b | sheet c | sheet d | sheet b | sheet c |
| | Middle layer | | Green | Green | Green | Green | Green | Green |
| | (520 μm thick) | | sheet a | sheet a | sheet a | sheet d | sheet b | sheet c |
| | Lower layer | | Green | Green | Green | Green | Green | Green |
| | (130 μm thick) | | sheet a | sheet b | sheet c | sheet d | sheet b | sheet c |
| Characteristics | Three-point bending | | 291 | 348 | 320 | 478 | 296 | 210 |
| | strength [MPa] | | | | | | | |
| | Reflectivity[%] (460 nm) | | 96 | 93 | 93 | 98 | 91 | 91 |
| | Light shielding property | | A | A | A | A | B | B |
| | Housing color | (L*) | 97.8 | 97.3 | 96.8 | 97.8 | 96.3 | 95.3 |
| | | (a*) | 0.19 | −0.14 | 0.39 | −0.14 | 0.05 | 0.52 |
| | | (b*) | 0.54 | 1.47 | 1.18 | 0.88 | 1.04 | 0.99 |

As is clear from Table 8, regarding test pieces of examples 24 to 27, the color tone is white and the light shielding property is excellent because of having reflectivity of 92% or more, where it can be seen that it is preferable for the portable electronic device housing. Among them, the test pieces of examples 25 to 27 have strength of 300 MPa or more, and it can be seen that particularly the test piece of example 27 excels in strength. On the other hand, regarding the test pieces of examples 28, 29, the color tone is white but their reflectivity is less than 92%, and hence it can be seen that their transmittance is high, that is, light shielding property is insufficient.

Note that the reflectivity by a single high reflectivity layer is described. In the case of a high reflectivity layer constituted of the green sheet “a”, reflectivity was 92% by a thickness of 300 μm and 94% by a thickness of 520 μm. In the case of a high reflectivity layer constituted of the green sheet “d”, reflectivity was 92% by a thickness of 300 μm and 95% by a thickness of 520 μm. It can be seen that a sufficient light shielding property can be obtained by using these layers.

According to the present invention, a glass ceramic body which has a sufficiently high strength and has a high degree of flexibility in shape which can correspond to a three-dimensional shape, and a layered body having this glass ceramic body can be provided, which are expected to be used as a wiring board used for various electronic devices and as a housing for electronic device such as a portable phone.

What is claimed is:

1. A glass ceramic body, comprising a glass matrix constituted of a glass with a crystallinity of 25% or less and flat alumina particles dispersed in the glass matrix, and an open porosity of the glass ceramic body being 5% or less,
wherein the glass ceramic body is obtained by forming a glass ceramic composition into a green sheet and thereafter firing the green sheet; the glass ceramic composition contains glass particles and the flat alumina particles having a mean thickness of 0.4 μm or more, a mean major axis of 10 μm or less, and a mean aspect ratio of 3 to 18; and a content of the flat alumina particles in the composition is 25 vol % or more.

2. A glass ceramic body, comprising a glass matrix and flat alumina particles dispersed in the glass matrix,
wherein:
the glass matrix is constituted of a glass with a crystallinity of 25% or less;
the flat alumina particles are dispersed in the glass matrix in a direction in which individual thickness directions are substantially perpendicular to a surface direction of one of surfaces of the glass ceramic body;
a total cross-sectional area of the flat alumina particles, having a cross section with a thickness of 0.2 μm or more, a maximum diameter of 8 μm or less, and an aspect ratio in a range of 3 to 18 in one of cross sections along the thickness directions of the flat alumina particles in the glass ceramic body, is 20% or more relative to a total area of the cross section; and
an open porosity of the glass ceramic body is 5% or less.

3. The glass ceramic body according to claim 2,
wherein the flat alumina particles are dispersed in the glass matrix so that their individual major axis directions are substantially in a same direction, and the cross section is substantially parallel with the major axis directions of the flat alumina particles.

4. The glass ceramic body according to claim 1,
wherein the glass matrix is constituted of a glass with a crystallinity of 15% or less.

5. The glass ceramic body according to claim 2,
wherein the glass matrix is constituted of a glass with a crystallinity of 15% or less.

6. The glass ceramic body according to claim 1,
wherein the glass constituting the glass matrix is SiO₂—B₂O₃—CaO based glass containing components derived from Al₂O₃ and, 10% or more of CaO in mole percentage based on oxides when a composition of the glass excluding Al₂O₃ is 100%.

7. The glass ceramic body according to claim 6,
wherein the glass constituting the glass matrix contains SiO₂, B₂O₃, and CaO by 75% or more in total in mole percentage based on oxides when a composition of the glass excluding Al₂O₃ is 100%.

8. The glass ceramic body according to claim 2,
wherein the glass constituting the glass matrix is SiO₂—B₂O₃—CaO based glass containing components derived from Al₂O₃ and, 10% or more of CaO in mole percentage based on oxides when a composition of the glass excluding Al₂O₃ is 100%.

9. The glass ceramic body according to claim 8,
wherein the glass constituting the glass matrix contains SiO₂, B₂O₃, and CaO by 75% or more in total in mole percentage based on oxides when a composition of the glass excluding Al₂O₃ is 100%.

10. The glass ceramic body according to claim 1,
wherein a three-point bending strength of the glass ceramic body is more than 400 MPa.

11. The glass ceramic body according to claim 2,
wherein a three-point bending strength of the glass ceramic body is more than 400 MPa.

12. A layered body comprising the glass ceramic body according to claim 1.

13. A layered body comprising the glass ceramic body according to claim 2.

14. A portable electronic device housing used as a housing of a portable electronic device, comprising a high reflectivity layer constituted of a glass ceramic body, and having reflectivity of 92% or more in a wavelength range of at least 400 to 800 nm.

15. The portable electronic device housing according to claim 14,
wherein:
the glass ceramic body is a sintered compact in which flat alumina particles are dispersed in a glass matrix;
the flat alumina particles are dispersed in the glass matrix in a direction in which individual thickness directions are substantially perpendicular to a surface direction of one of surfaces of the glass ceramic body; and
in one of cross sections along the thickness directions of the flat alumina particles in the glass ceramic body, flat alumina particles having a thickness of 0.2 to 1 μm, a length of 1 to 5 μm, and an aspect ratio in a range of 3 to 18 in the cross section are contained.

16. The portable electronic device housing according to claim 14,
wherein the glass ceramic body is a sintered compact in which high refractive index ceramic particles of at least one selected from titania particles, zirconia particles, and niobium oxide particles are dispersed in the glass matrix.

17. The portable electronic device housing according to claim 14, comprising a pair of low thermal expansion layers constituted of a glass ceramic having a smaller thermal expansion coefficient than the high reflectivity layer on both main surface sides of the high reflectivity layer.

18. The portable electronic device housing according to claim 14, comprising a pair of low contraction layers constituted of a glass ceramic having a smaller firing contraction ratio than the high reflectivity layer on both main surface sides of the high reflectivity layer.

19. The portable electronic device housing according to claim 14, comprising a glassy layer on an uppermost surface of at least one of main surface sides of the high reflectivity layer.

20. The portable electronic device housing according to claim 14,
wherein a thickness of the high reflectivity layer is 300 μm or more.
